(19) United States
(12) Patent Application Publication
(10) Pub. No.: US 2025/0344451 A1
(43) Pub. Date: Nov. 6, 2025

(54) Semiconductor Devices and Methods of Forming the Same

(71) Applicant: Taiwan Semiconductor Manufactuering Co., Ltd.., Hsinchu (TW)

(72) Inventors: Li-Wei Yin, Hsinchu (TW); Yun-Chen Wu, Hsinchu (TW); Tzu-Wen Pan, Hsinchu (TW); Jih-Sheng Yang, Hsinchu (TW); Yu-Hsien Lin, Kaohsiung City (TW); Ryan Chia-Jen Chen, Hsinchu (TW)

(21) Appl. No.: 19/270,874

(22) Filed: Jul. 16, 2025

Related U.S. Application Data
(62) Division of application No. 17/730,797, filed on Apr. 27, 2022.
(60) Provisional application No. 63/224,472, filed on Jul. 22, 2021.

(51) Int. Cl. H10D 30/67; H10D 30/01; H10D 62/10; H10D 64/01; H10D 64/27; H10D 84/01; H10D 84/03; H10D 84/85

(52) U.S. Cl. CPC H10D 30/6735; H10D 30/014; H10D 30/031; H10D 30/6757; H10D 62/118; H10D 62/121; H10D 64/01; H10D 64/017; H10D 64/519; H10D 84/0172; H10D 84/0184; H10D 84/0186; H10D 84/038; H10D 84/85

(57) ABSTRACT

Improved gate structures, methods for forming the same, and semiconductor devices including the same are disclosed. In an embodiment, a semiconductor device includes a gate structure over a semiconductor substrate, the gate structure including a high-k dielectric layer; a gate electrode over the high-k dielectric layer; a conductive cap over and in contact with the high-k dielectric layer and the gate electrode, a top surface of the conductive cap being convex; and first gate spacers on opposite sides of the gate structure, the high-k dielectric layer and the conductive cap extending between opposite sidewalls of the first gate spacers.

### CROSS-REFERENCE TO RELATED APPLICATIONS

This application is a divisional of U.S. patent application Ser. No. 17/730,797, filed on Apr. 27, 2022, which claims the benefit of U.S. Provisional Application No. 63/224,472, filed on Jul. 22, 2021, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B, 7C, 8A, 8B, 8C, 9A, 9B, 9C, 10A, 10B, 10C, 11A, 11B, 11C, 11D, 12A, 12B, 12C, 12D, 12E, 13A, 13B, 14A, 14B, 15A, 15B, 16A, 16B, 17A, 17B, 18A, 18B, 18C, 19A, 19B, 19C, 20A, 20B, 20C, 21A, 21B, 21C, 22A, 22B, 22C, 22D, 22E, 23A, 23B, 24A, 24B, 25A, and 25B are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide improved gate structures, methods of forming the improved gate structures, and semiconductor devices including the improved gate structures. The method includes replacing a dummy gate structure with a replacement gate structure, etching back the replacement gate structure, and selectively depositing an etch barrier over the replacement gate structure. The etch barrier may be deposited with a greater thickness over the center of the replacement gate structure. As such, the etch barrier and the replacement gate structure may be etched back such that the replacement gate structure has a flat top surface or a convex top surface. A conductive cap may then be deposited over the replacement gate structure. The conductive cap may be deposited over the replacement gate structure with a flat top surface or a convex top surface. A gate mask may then be formed over the conductive cap. The gate mask may then be etched to form openings in which contacts to the conductive cap are formed. Forming an improved gate structure (including the replacement gate structure and the conductive cap) according to the method and having the flat top surface or the convex top surface may reduce under-etching of the gate mask, which reduces device defects and improves device performance. Further, forming the conductive cap with the flat top surface or the convex top surface may increase a distance between the conductive cap and subsequently formed source/drain contacts, which improves a bridge window between the improved gate structure and the source/drain contacts, reduces device defects, and improves device performance.

Embodiments are described below in a particular context, i.e., a die comprising nanostructure FETs. Various embodiments may be applied, however, to dies comprising other types of transistors (e.g., fin field effect transistors (FinFETs), planar transistors, or the like) in lieu of or in combination with the nanostructure FETs.

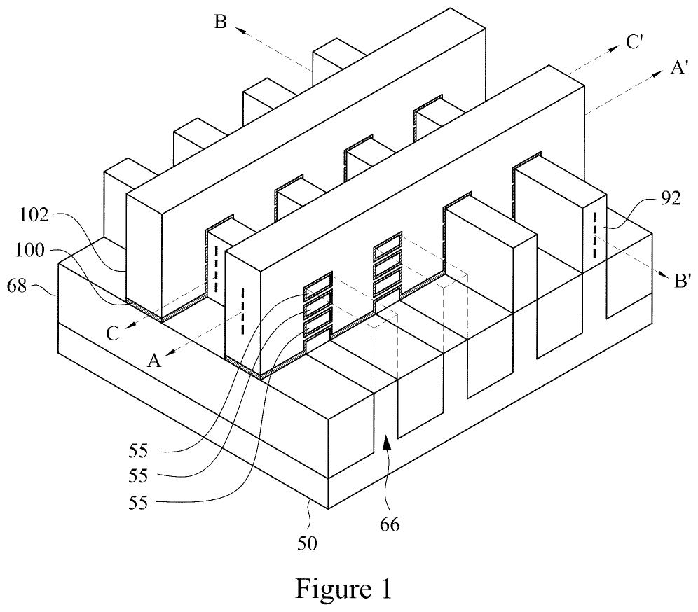

FIG. 1 illustrates an example of nanostructure FETs (e.g., nanowire FETs, nanosheet FETs (Nano-FETs), or the like) in a three-dimensional view. The nano-FETs comprise nanostructures 55 (e.g., nanosheets, nanowires, or the like) over fins 66 on a substrate 50 (e.g., a semiconductor substrate). The nanostructures 55 act as channel regions for the nanostructure FETs. The nanostructures 55 may include p-type nanostructures, n-type nanostructures, or a combination thereof. Isolation regions 68 are disposed between adjacent fins 66. The fins 66 may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 is illustrated as being a single, continuous material with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces and sidewalls of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nanostructure FET. Cross-section B-B′ is perpendicular to cross-section A-A′ and is parallel to a longitudinal axis of a fin 66 of the nanostructure FET and in a direction of, for example, the current flow between the epitaxial source/drain regions 92 of the nanostructure FET. Cross-section C-C′ is parallel to cross-section A-A′ and extends through the epitaxial source/drain regions 92 of the nanostructure FET. Subsequent figures refer to these reference cross-sections for clarity.

Some embodiments discussed herein are discussed in the context of nanostructure FETs formed using a gate-last process. In other embodiments, a gate-first process may be used. Also, some embodiments contemplate aspects used in planar devices, such as planar FETs, or in fin field-effect transistors (FinFETs).

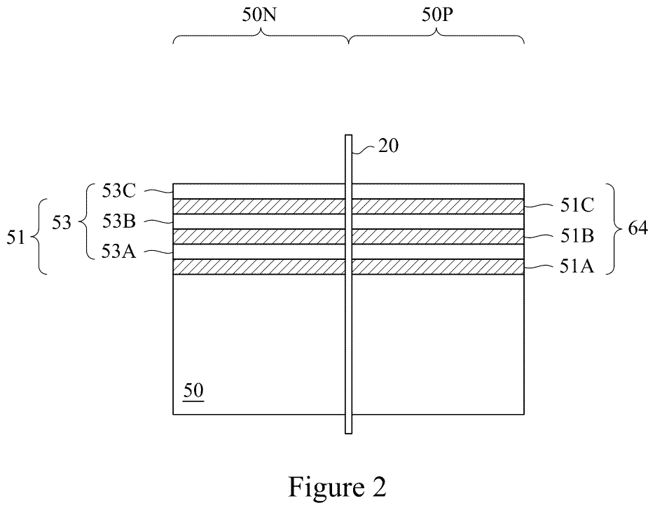

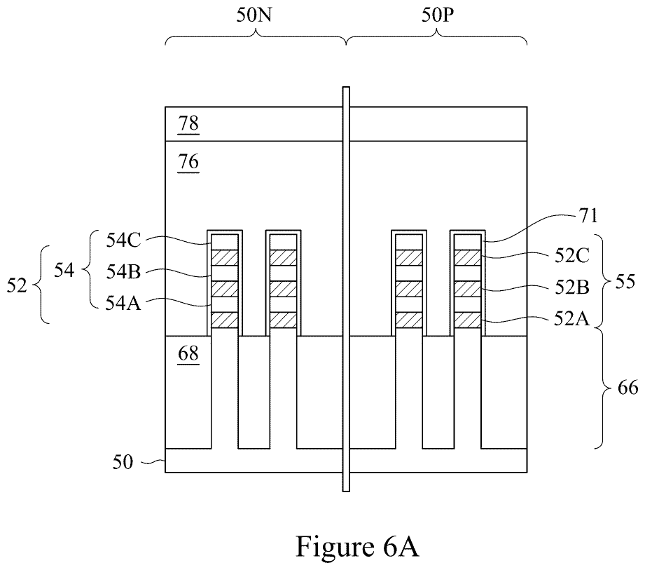

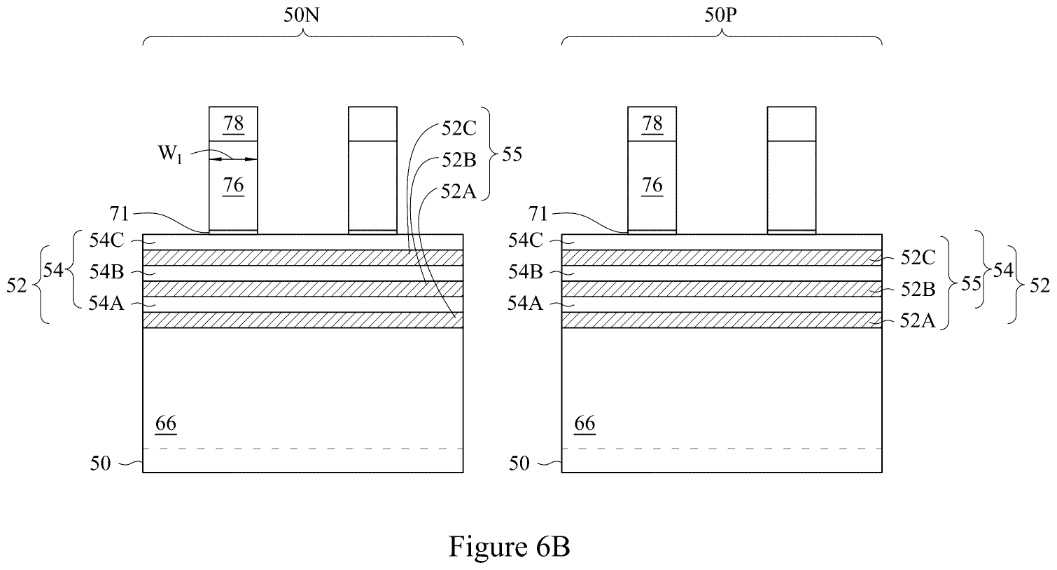

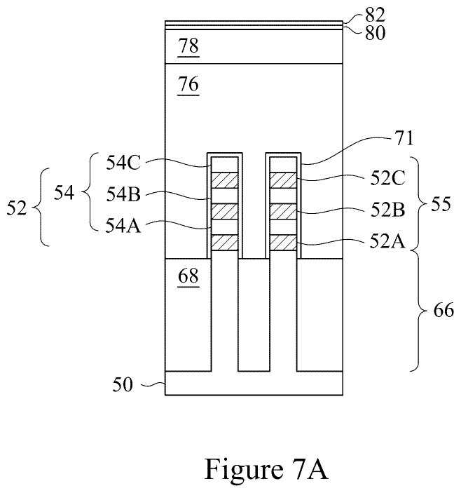

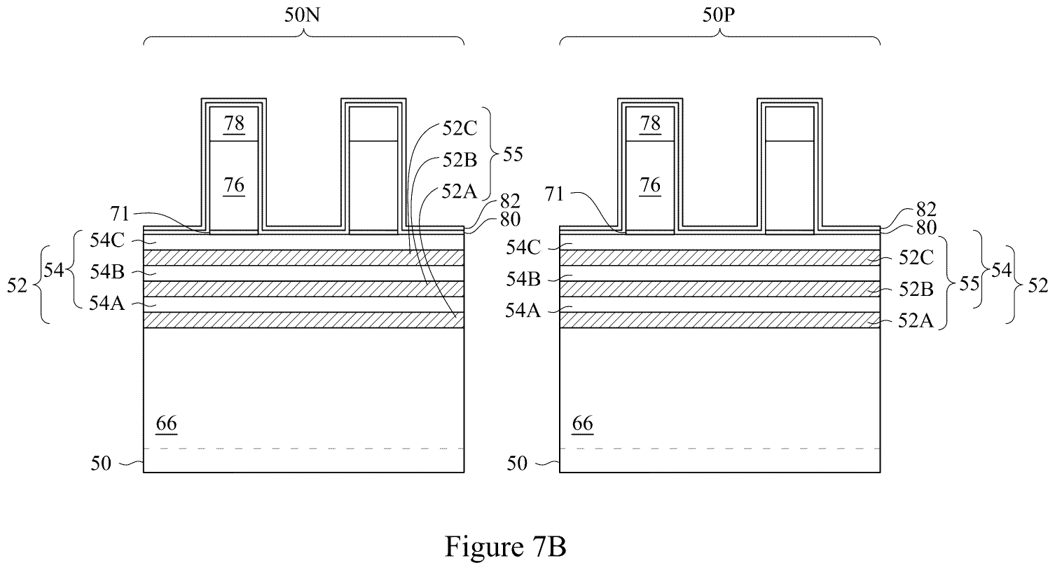

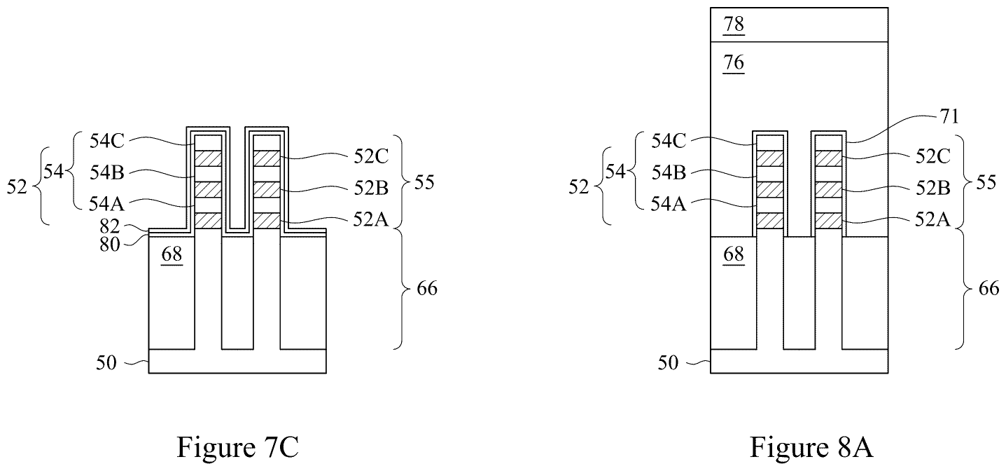

FIGS. 2 through 25B are cross-sectional views of intermediate stages in the manufacturing of nanostructure FETs, in accordance with some embodiments. FIGS. 2 through 5, 6A, 7A, 8A, 9A, 10A, 11A, 12A, 13A, 14A, 15A, 16A, 17A, 18A, 19A, 20A, 21A, 22A, 23A, 24A, and 25A illustrate reference cross-section A-A′ illustrated in FIG. 1. FIGS. 6B, 7B, 8B, 9B, 10B, 11B, 11D, 12B, 12D, 13B, 14B, 15B, 16B, 17B, 18B, 18C, 19B, 19C, 20B, 20C, 21B, 21C, 22B, 22C, 22D, 22E, 23B, 24B, and 25B illustrate reference cross-section B-B′ illustrated in FIG. 1. FIGS. 7C, 8C, 9C, 10C, 11C, 12C, and 12E illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure FETs. The p-type region 50P can be for forming p-type devices, such as PMOS transistors, e.g., p-type nanostructure FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nanostructure FETs in the p-type region 50P. The first semiconductor layers 51 will be removed and the second semiconductor layers 53 will be patterned to form channel regions of nanostructure FETs in the n-type region 50N. Nevertheless, in some embodiments the first semiconductor layers 51 may be removed and the second semiconductor layers 53 may be patterned to form channel regions of nanostructure FETs in the p-type region 50P, and the second semiconductor layers 53 may be removed and the first semiconductor layers 51 may be patterned to form channel regions of nanostructure FETs in the n-type region 50N.

In some embodiments, the first semiconductor layers 51 may be removed and the second semiconductor layers 53 may be patterned to form channel regions of nanostructure FETS in both the n-type region 50N and the p-type region 50P. In some embodiments, the second semiconductor layers 53 may be removed and the first semiconductor layers 51 may be patterned to form channel regions of nanostructure FETs in both the n-type region 50N and the p-type region 50P. In such embodiments, the channel regions in both the n-type region 50N and the p-type region 50P may have a same material composition (e.g., silicon, or another semiconductor material) and be formed simultaneously.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. The first semiconductor layers 51 may be formed of a first semiconductor material suitable for p-type nanostructure FETs, such as silicon germanium or the like. The second semiconductor layers 53 may be formed of a second semiconductor material suitable for n-type nanostructure FETs, such as silicon, silicon carbon, or the like. The multi-layer stack 64 is illustrated as having a bottommost semiconductor layer suitable for p-type nanostructure FETs (e.g., the first semiconductor layers 51) for illustrative purposes. In some embodiments, the multi-layer stack 64 may be formed such that the bottommost layer is a semiconductor layer suitable for n-type nanostructure FETs (e.g., the second semiconductor layers 53).

The first semiconductor materials and the second semiconductor materials may be materials having a high etch selectivity to one another. As such, the first semiconductor layers 51 formed of the first semiconductor materials may be removed without significantly removing the second semiconductor layers 53 formed of the second semiconductor materials in the n-type region 50N. This allows the second semiconductor layers 53 to be patterned to form channel regions of n-type nanostructure FETs. Similarly, the second semiconductor layers 53 formed of the second semiconductor materials may be removed without significantly removing the first semiconductor layers 51 formed of the first semiconductor materials in the p-type region 50P. This allows the first semiconductor layers 51 to be patterned to form channel regions of p-type nanostructure FETs.

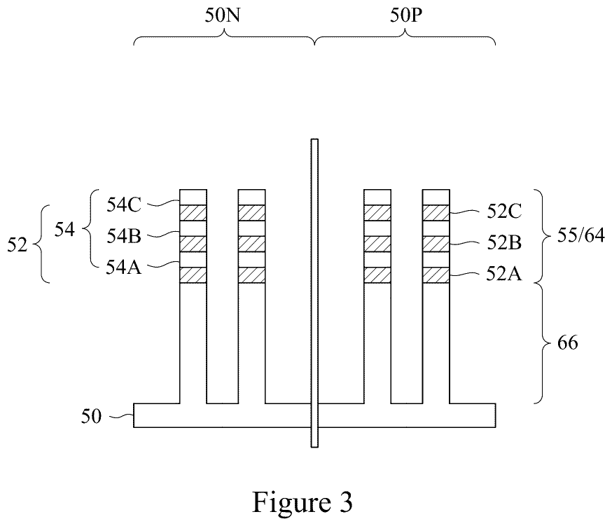

In FIG. 3, fins 66 are formed in the substrate 50 and nanostructures 55 are formed in the multi-layer stack 64. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as first nanostructures 52) from the first semiconductor layers 51 and define second nanostructures 54A-C (collectively referred to as second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers are used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater than or less than widths of the fins 66 in the p-type region 50P. Further, while each of the fins 66 and the nanostructures 55 are illustrated as having a consistent width throughout, in some embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and may be trapezoidal in shape.

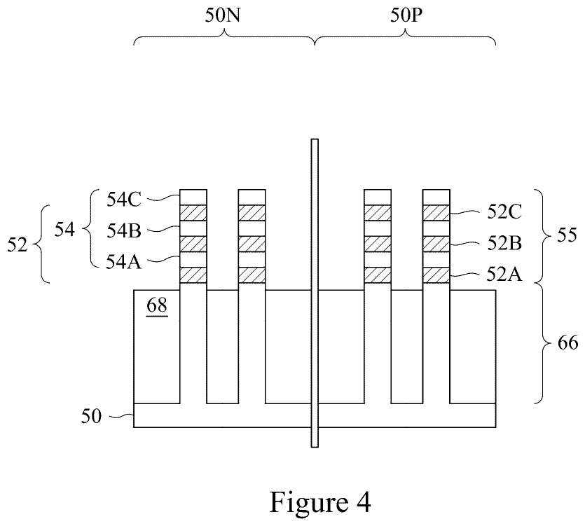

In FIG. 4, shallow trench isolation (STI) regions 68 are formed adjacent the fins 66. The STI regions 68 may be formed by depositing an insulation material over the substrate 50, the fins 66, and the nanostructures 55, and between adjacent fins 66. The insulation material may be an oxide (such as silicon oxide), a nitride, the like, or a combination thereof. The insulation material may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments, a liner (not separately illustrated) may be formed along surfaces of the substrate 50, the fins 66, and the nanostructures 55. Thereafter, a fill material, such as those discussed above, may be formed over the liner.

A removal process is then applied to the insulation material to remove excess insulation material over the nanostructures 55. In some embodiments, a planarization process, such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that the nanostructures 55 and upper portions of the fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etch process, such as one that is selective to the material of the insulation material (e.g., etches the material of the insulation material at a faster rate than the material of the fins 66 and the nanostructures 55). An oxide removal using dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth. This may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66, the nanostructures, and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

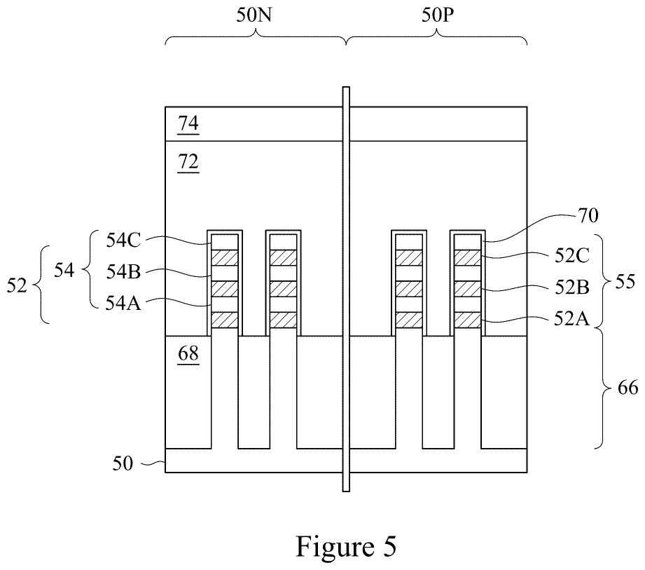

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques.

A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etch selectivity from the etching of isolation regions.

The mask layer 74 may be deposited over the dummy gate layer 72. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68. As such, the dummy dielectric layer 70 may extend between the dummy gate layer 72 and the STI regions 68.

FIGS. 6A through 25B illustrate various additional steps in the manufacturing of embodiment devices. FIGS. 7A, 7C, 8A, 8C, 9A, 9C, 10A, 10C, 11A, 11C, 12A, 12C, 12E, 13A, 14A, 15A, and 16A illustrate features in either the n-type regions 50N or the p-type regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the nanostructures 55. The pattern of the masks 78 may be used to physically separate each of the dummy gates 76 from adjacent dummy gates 76. The dummy gates 76 may also have a lengthwise direction substantially perpendicular to the lengthwise direction of respective fins 66. The masks 78, the dummy gates 76, and the dummy gate dielectrics 71 may be collectively referred to as “dummy gate structures.” The dummy gate structures may have widths W₁ ranging from about 1 nm to about 40 nm.

In FIGS. 7A through 7C, a first spacer layer 80 and a second spacer layer 82 are formed over dummy gate structures, the nanostructures 55, and the STI regions 68. The first spacer layer 80 and the second spacer layer 82 will be subsequently patterned to act as spacers for forming self-aligned source/drain regions. In FIGS. 7A through 7C, the first spacer layer 80 is formed on top surfaces of the STI regions 68; top surfaces and sidewalls of the nanostructures 55 and the masks 78; and sidewalls of the dummy gates 76, the dummy gate dielectrics 71, and the fins 66. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P. Appropriate type (e.g., p-type) impurities may be implanted into the exposed fins 66 and the nanostructures 55 in the p-type region 50P. The mask may then be removed. Subsequently, a mask, such as a photoresist, may be formed over the p-type region 50P while exposing the n-type region 50N. Appropriate type impurities (e.g., n-type) may be implanted into the exposed fins 66 and the nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

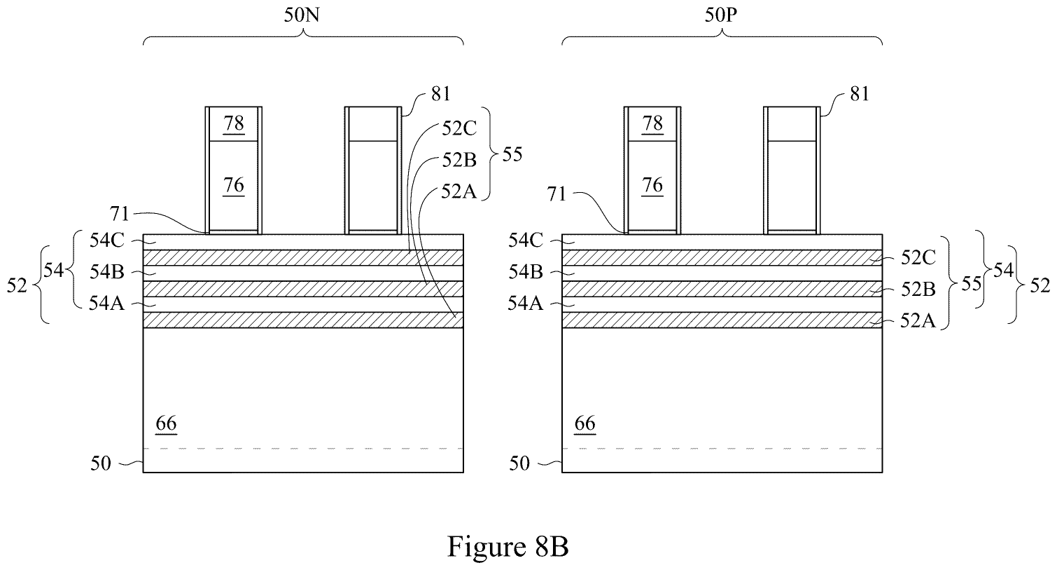

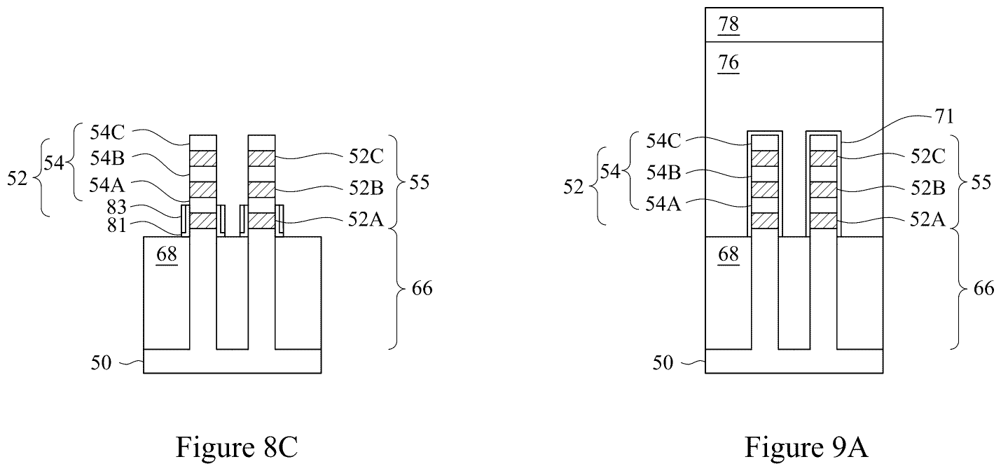

In FIGS. 8A through 8C, the first spacer layer 80 and the second spacer layer 82 (see FIGS. 7A through 7C) are etched to form first spacers 81 and second spacers 83. As will be discussed in greater detail below, the first spacers 81 and the second spacers 83 act to self-align subsequently formed source drain regions, as well as to protect sidewalls of the fins 66 and/or the nanostructure 55 during subsequent processing. The first spacer layer 80 and the second spacer layer 82 may be etched using a suitable etch process, such as an isotropic etch process (e.g., a wet etch process), an anisotropic etch process (e.g., a dry etch process), or the like. In some embodiments, the material of the second spacer layer 82 has a different etch rate than the material of the first spacer layer 80, such that the first spacer layer 80 may act as an etch stop layer when patterning the second spacer layer 82 and the second spacer layer 82 may act as a mask when patterning the first spacer layer 80. For example, the second spacer layer 82 may be etched using an anisotropic etch process wherein the first spacer layer 80 acts as an etch stop layer. Remaining portions of the second spacer layer 82 form second spacers 83, as illustrated in FIG. 8C. The second spacers 83 then act as a mask while etching exposed portions of the first spacer layer 80, thereby forming first spacers 81 as illustrated in FIGS. 8B and 8C.

As illustrated in FIG. 8C, the first spacers 81 and the second spacers 83 are disposed on sidewalls of the fins 66 and/or the nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and only the first spacers 81 are disposed on sidewalls of the masks 78, the dummy gates 76, and the dummy dielectric layers 60. In some embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

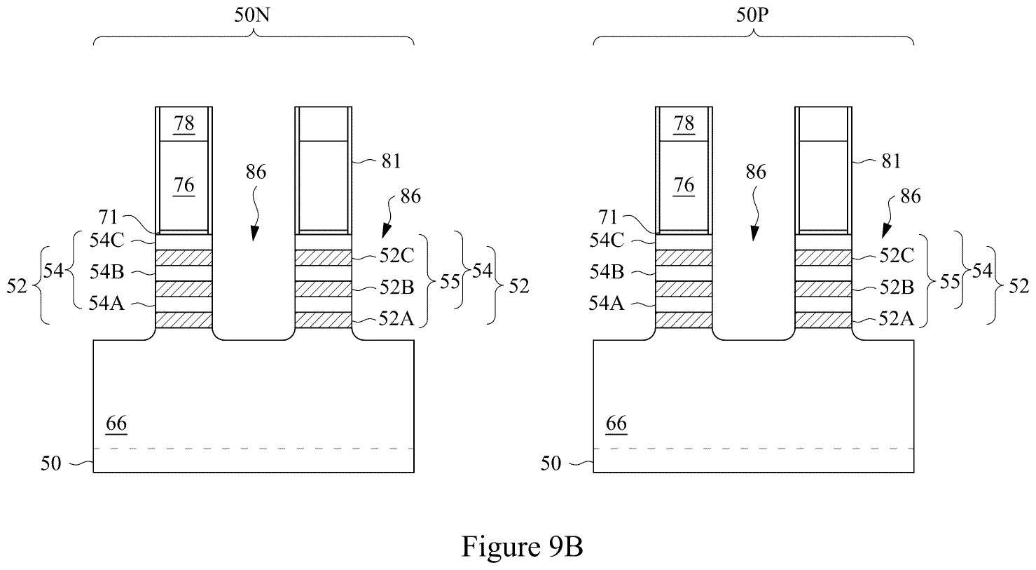

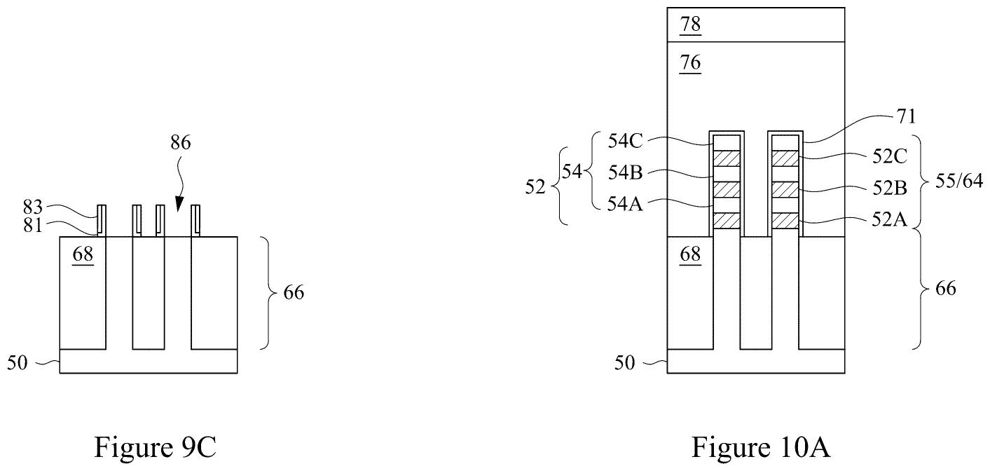

In FIGS. 9A through 9C, first recesses 86 are formed in the nanostructures 55, the fins 66, and the substrate 50. Epitaxial source/drain regions will be subsequently formed in the first recesses 86. The first recesses 86 may extend through the first nanostructures 52, the second nanostructures 54, and into the substrate 50. As illustrated in FIG. 9C, top surfaces of the STI regions 68 may be level with bottom surfaces of the first recesses 86. In various embodiments, the fins 66 may be etched such that bottom surfaces of the first recesses 86 are disposed above the top surfaces of the STI regions 68, below the top surfaces of the STI regions 68, or the like. The first recesses 86 may be formed by etching the nanostructures 55, the fins 66, and the substrate 50 using an anisotropic etch processes, such as RIE, NBE, or the like. The first spacers 81, the second spacers 83, and the masks 78 mask portions of the nanostructures 55, the fins 66, and the substrate 50 during the etch processes used to form the first recesses 86. A single etch process or multiple etch processes may be used to etch each layer of the nanostructures 55, the fins 66, and/or the substrate 50. Timed etch processes may be used to stop the etching of the first recesses 86 after the first recesses 86 reach a desired depth.

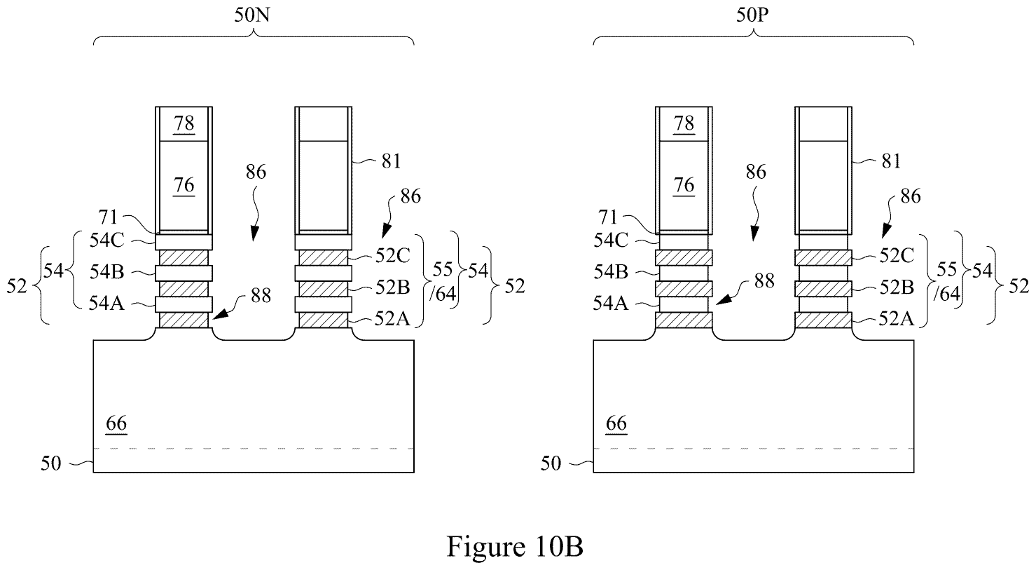

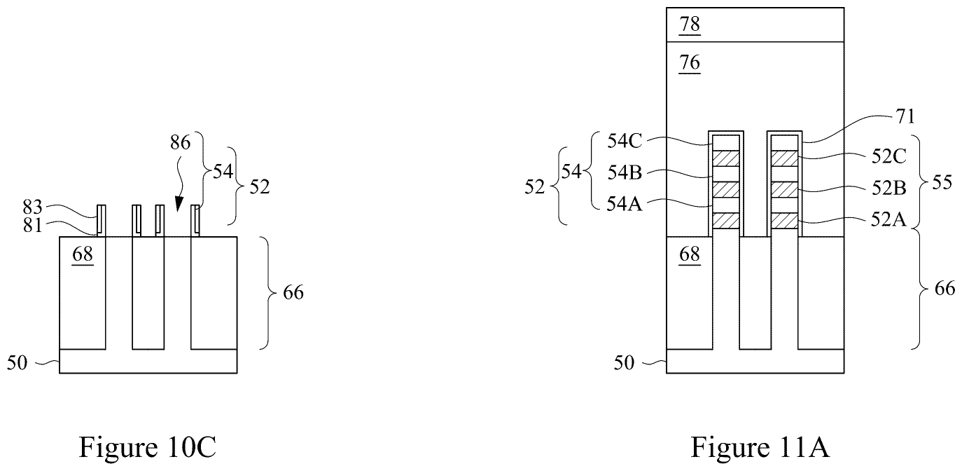

In FIGS. 10A through 10C, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 64 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 adjacent the sidewall recesses 88 are illustrated as being straight in FIG. 10B, the sidewalls may be concave or convex. The sidewalls may be etched using isotropic etch processes, such as a wet etch or the like. The p-type region 50P may be protected using a mask (not separately illustrated), while etchants selective to the first semiconductor materials are used to etch the first nanostructures 52. As such, the second nanostructures 54 and the substrate 50 in the n-type region 50N remain relatively un-etched as compared to the first nanostructures 52. Similarly, the n-type region 50N may be protected using a mask (not separately illustrated), while etchants selective to the second semiconductor materials are used to etch the second nanostructures 54. As such, the first nanostructures 52 and the substrate 50 in the p-type region 50P remain relatively un-etched as compared to the second nanostructures 54. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N. A wet or dry etch process with hydrogen fluoride, another fluorine-based etchant, or the like may be used to etch sidewalls of the second nanostructures 54 in the p-type region 50P.

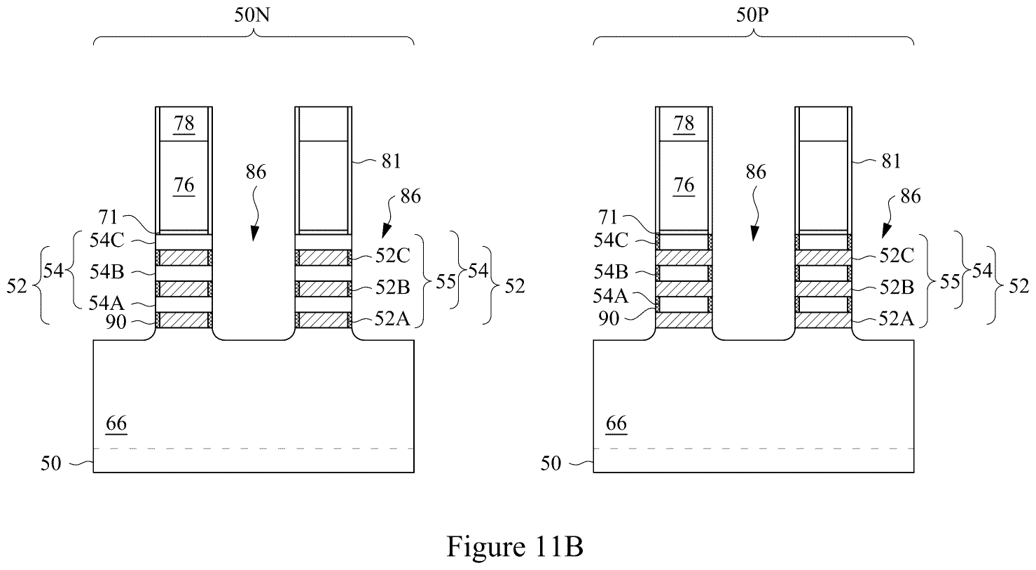

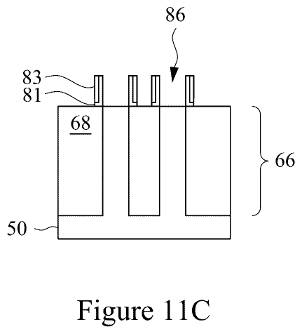

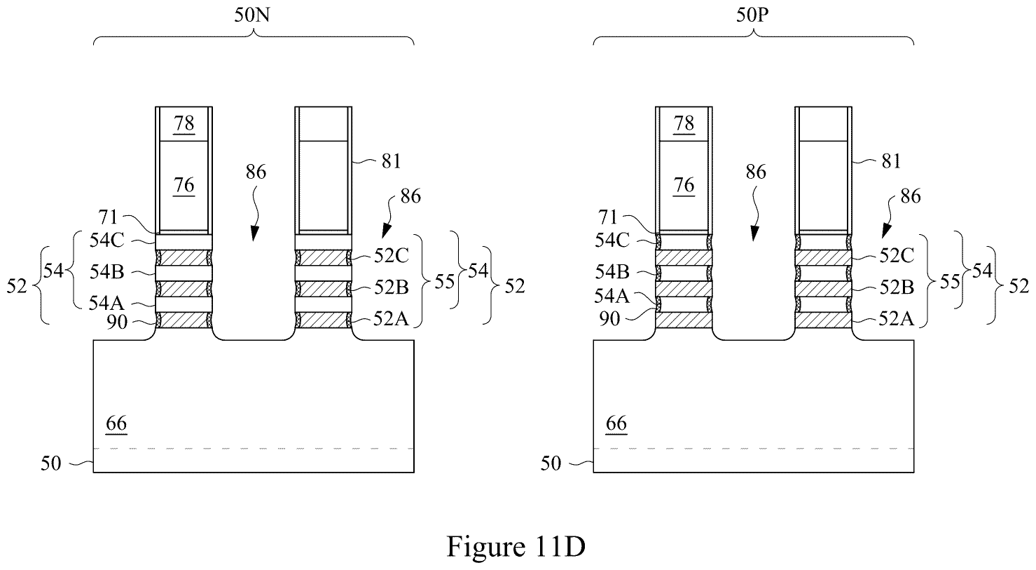

In FIGS. 11A through 11D, first inner spacers 90 are formed in the sidewall recesses 88. The first inner spacers 90 may be formed by depositing an inner spacer layer (not separately illustrated) over the structures illustrated in FIGS. 10A through 10C. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may be anisotropically etched to form the first inner spacers 90, using a process such as RIE, NBE, or the like.

Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52. Moreover, although the outer sidewalls of the first inner spacers 90 are illustrated as being straight in FIG. 11B, the outer sidewalls of the first inner spacers 90 may be concave or convex. As an example, FIG. 11D illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Further in FIG. 11D, sidewalls of the second nanostructures 54 are concave, outer sidewalls of the first inner spacers 90 are concave, and the first inner spacers 90 are recessed from sidewalls of the first nanostructures 52 in the p-type region 50P.

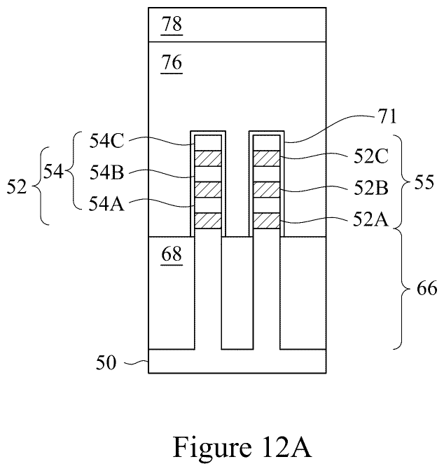

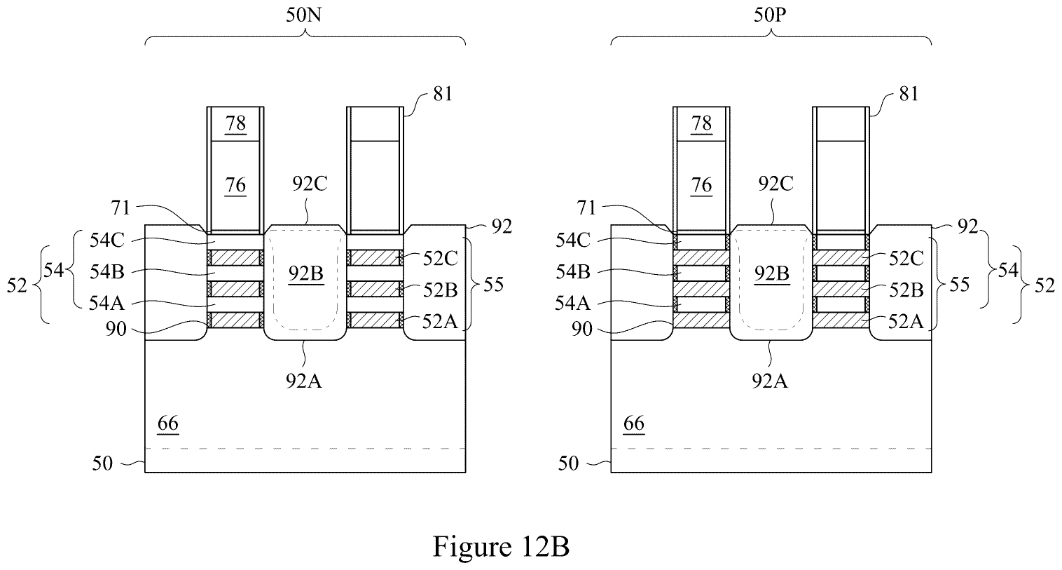

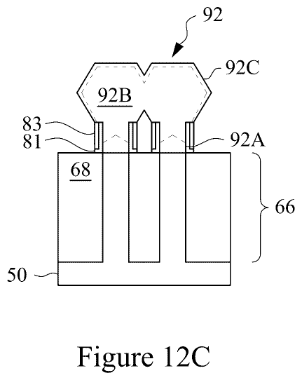

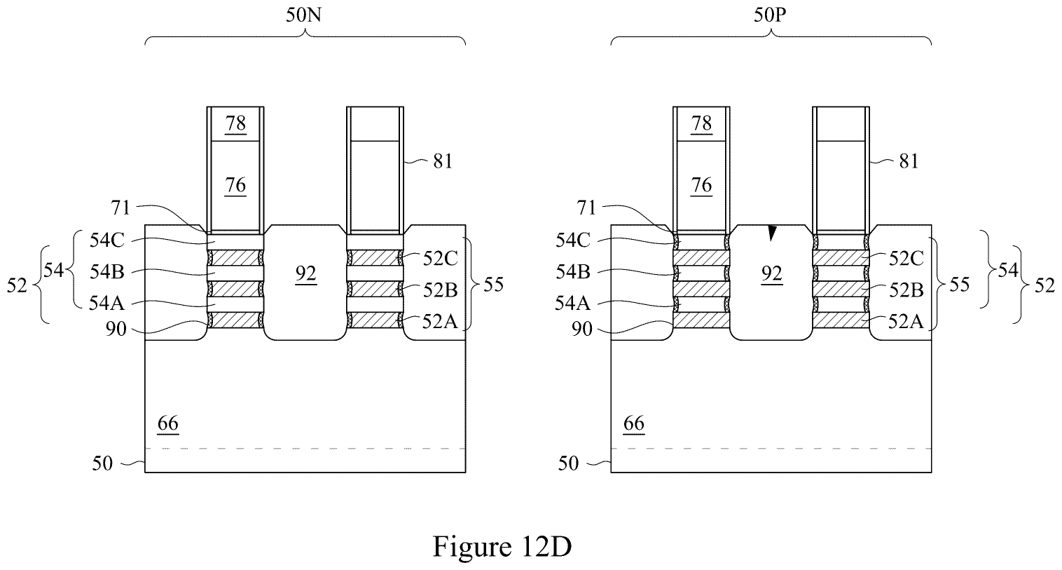

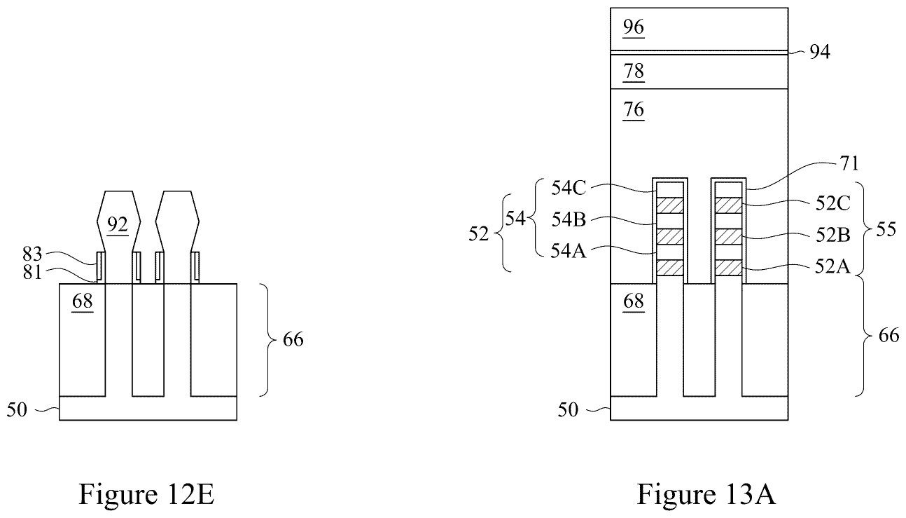

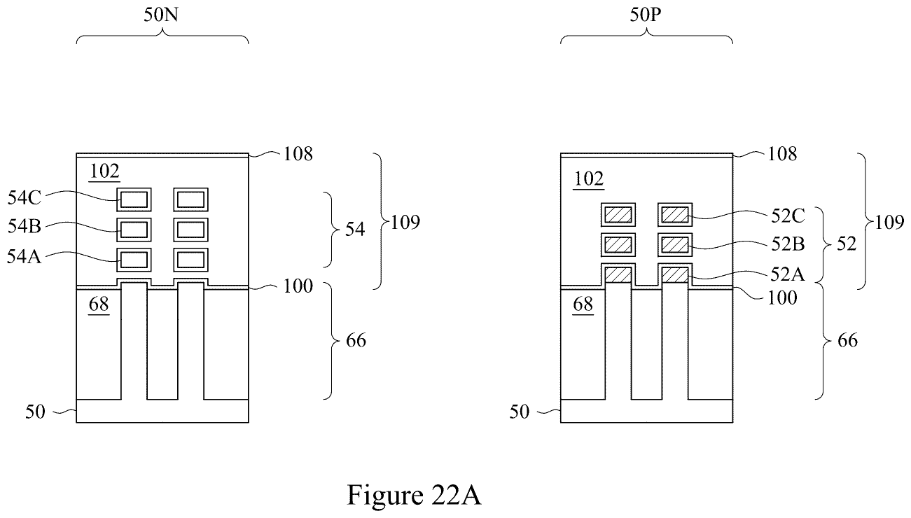

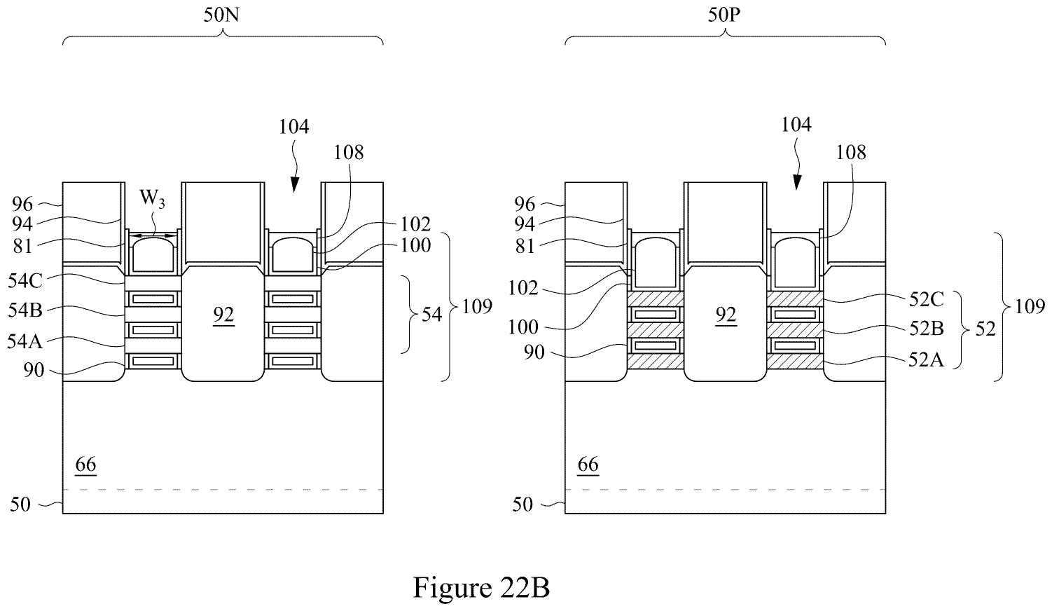

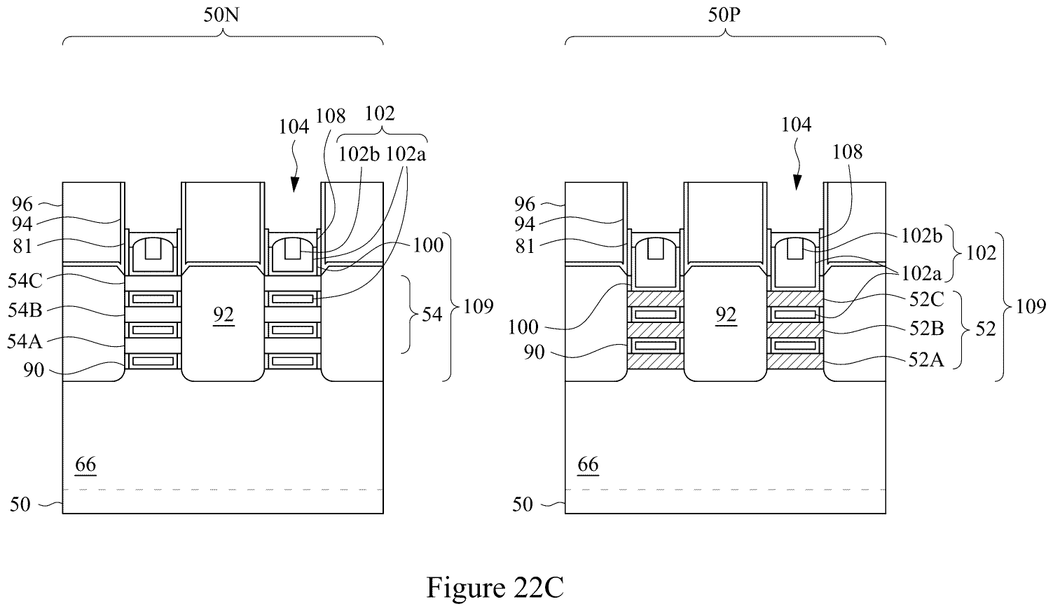

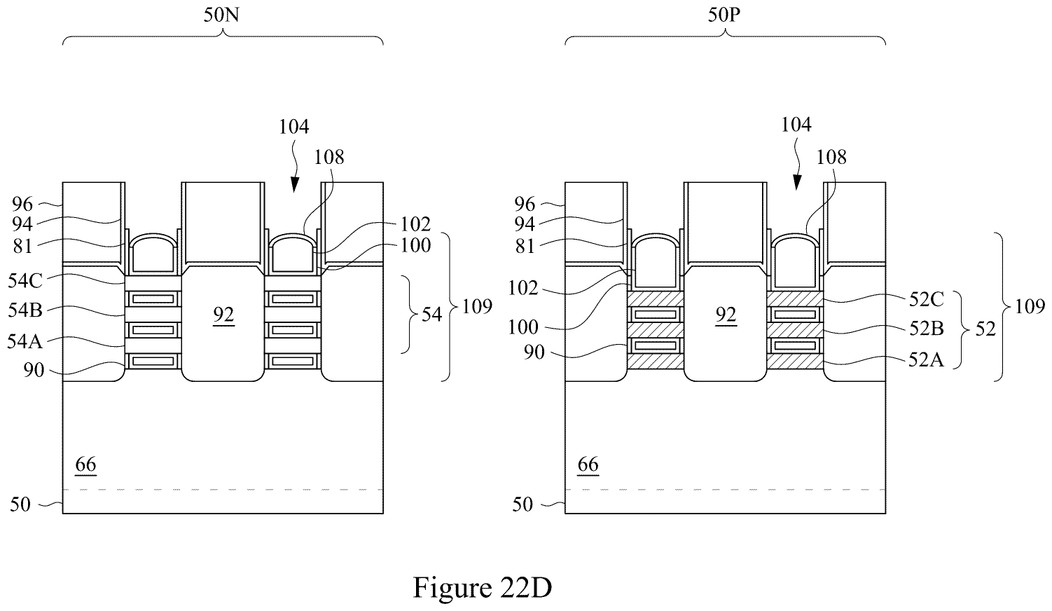

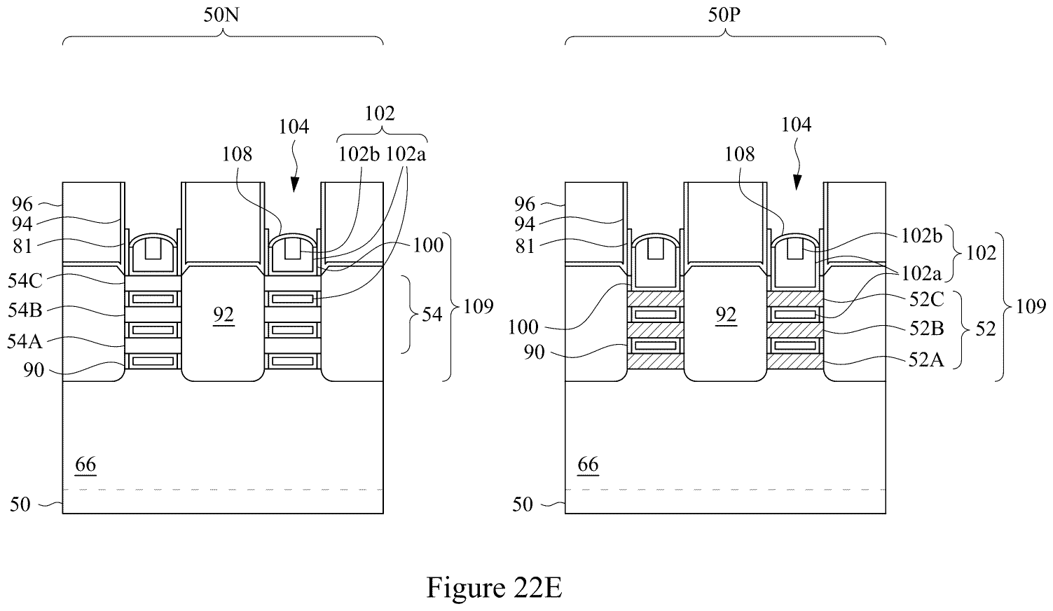

The first inner spacers 90 act as isolation features between subsequently formed source/drain regions (such as the epitaxial source/drain regions 92, discussed below with respect to FIGS. 12A through 12E) and gate structures (such as the gate structures including the gate dielectric layers 100, the gate electrodes 102, and the conductive caps 108, discussed below with respect to FIGS. 22A through 22E). The first inner spacers 90 may be also prevent damage to the epitaxial source/drain regions 92 by subsequent etching processes, such as etching processes used to form the gate structures.

In FIGS. 12A through 12E, epitaxial source/drain regions 92 (which may include a first semiconductor material layer 92A, a second semiconductor material layer 92B, and a third semiconductor material layer 92C) are formed in the first recesses 86 (illustrated in FIGS. 11B through 11D). In some embodiments, the epitaxial source/drain regions 92 may exert stress on the second nanostructures 54 in the n-type region 50N and on the first nanostructures 52 in the p-type region 50P, thereby improving performance. As illustrated in FIG. 12B, the epitaxial source/drain regions 92 are formed in the first recesses 86 such that each of the dummy gates 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by appropriate lateral distances to prevent shorts between the epitaxial source/drain regions 92 and subsequently formed gate structures (such as the gate structures including the gate dielectric layers 100, the gate electrodes 102, and the conductive caps 108, discussed below with respect to FIGS. 22A through 22E).

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nanostructure FETs. For example, in embodiments in which the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nanostructure FETs. For example, in embodiments in which the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the nanostructures 55 and may have facets.

The epitaxial source/drain regions 92, the nanostructures 55, the fins 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for the source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nanostructure FET to merge, as illustrated by FIG. 12C. In other embodiments, adjacent epitaxial source/drain regions 92 remain separated after the epitaxy process is completed, as illustrated by FIG. 12E. In the embodiments illustrated in FIGS. 12C and 12E, the first spacers 81 may be formed extending to top surfaces of the STI regions 68, thereby blocking the epitaxial growth. In some embodiments, the first spacers 81 may cover portions of the sidewalls of the nanostructures 55, further blocking the epitaxial growth. In some embodiments, the spacer etch used to form the first spacers 81 may be adjusted to remove the spacer material, allowing the epitaxial source/drain regions 92 to extend to the surfaces of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52. As illustrated in FIG. 12D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

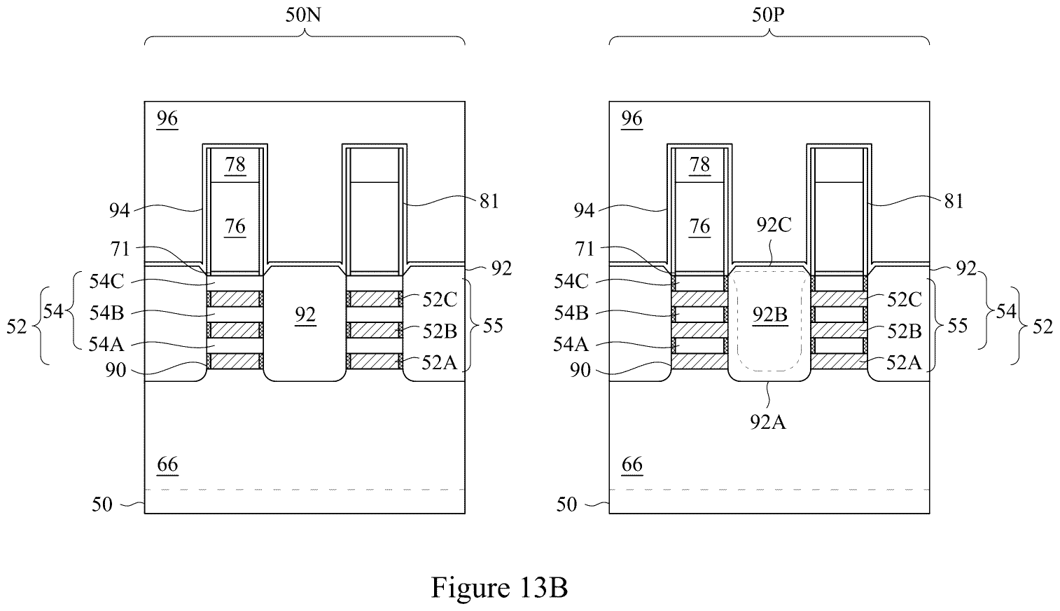

In FIGS. 13A and 13B, a contact etch stop layer (CESL) 94 and a first interlayer dielectric (ILD) 96 are deposited over the epitaxial source/drain regions 92, the dummy gate structures, and the first spacers 81. The CESL 94 may comprise a dielectric material, such as, silicon nitride, silicon oxide, silicon oxynitride, or the like, having a different etch rate than the material of the overlying first ILD 96. The CESL 94 may be deposited by ALD, CVD, or the like. The CESL 94 may be optional and may be omitted in some embodiments. The first ILD 96 may be formed of a dielectric material, and may be deposited by any suitable method, such as CVD, plasma-enhanced CVD (PECVD), or FCVD. Suitable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

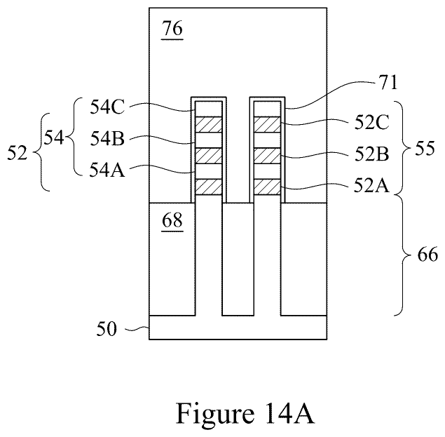

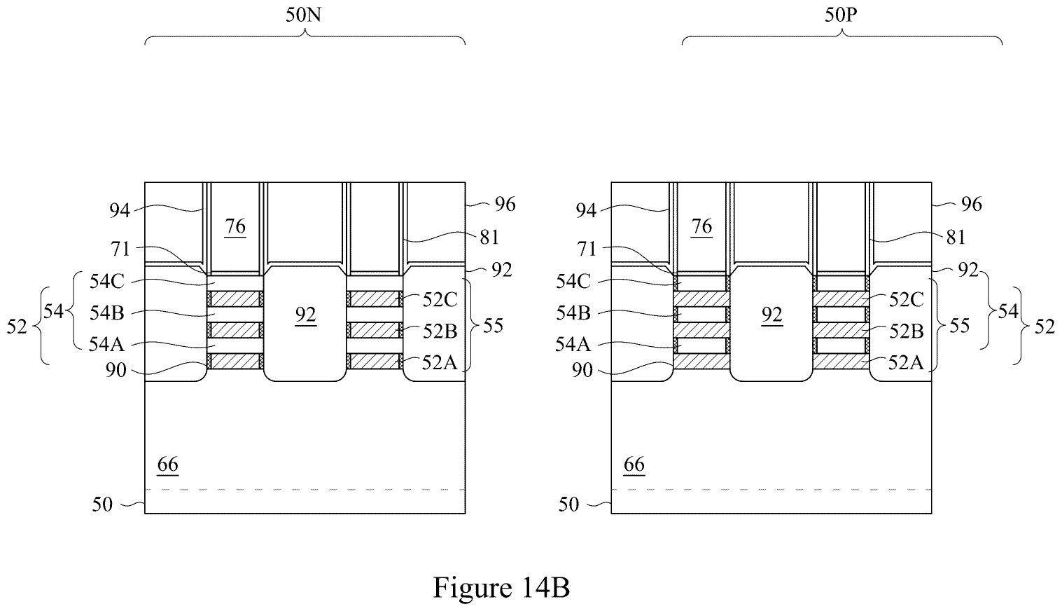

In FIGS. 14A and 14B, a planarization process, such as a CMP, is performed to level top surfaces of the first ILD 96 with top surfaces of the dummy gates 76. The planarization process may remove the masks 78 on the dummy gates 76, and portions of the first spacers 81 along sidewalls of the masks 78. After the planarization process, top surfaces of the dummy gates 76, the first spacers 81, the CESL 94, and the first ILD 96 are level with one another (within process variations). Accordingly, the top surfaces of the dummy gates 76 are exposed through the first ILD 96 and the CESL 94.

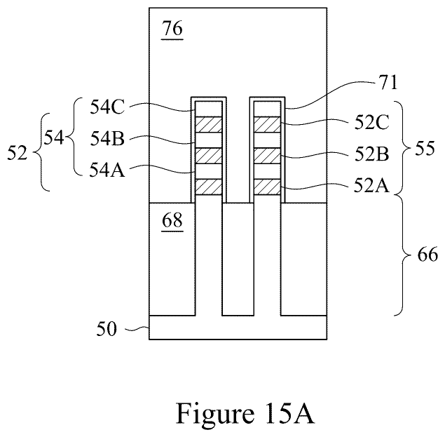

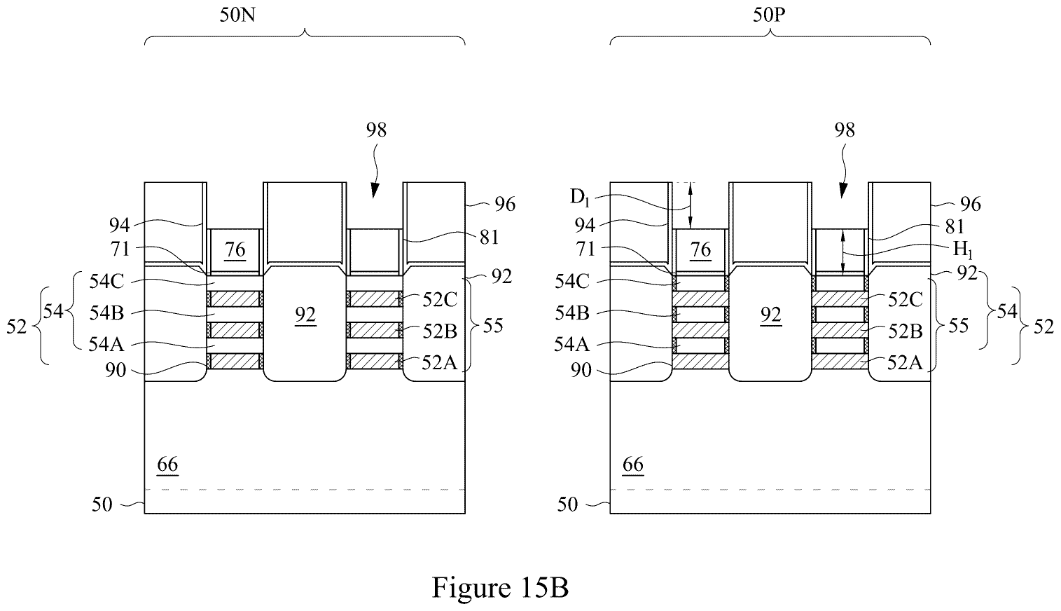

In FIGS. 15A and 15B, the dummy gates 76 and the first spacers 81 are etched back forming second recesses 98. In some embodiments, the dummy gates 76 and the first spacers 81 are etched back by one or more etch processes, such as anisotropic dry etch processes, isotropic wet etch processes, or the like. In some embodiments, the dummy gates 76 may be etched back prior to the first spacers 81 being etched back. The etch processes may include a dry etch process using reaction gas(es) that selectively etch the dummy gates 76 (at a faster rate than the first ILD 96, the CESL 94, or the first spacers 81); a dry etch process using reaction gas(es) that selectively etch the first spacers 81 (at a faster rate than the first ILD 96, the CESL 94, or the dummy gates 76); a dry etch process using reaction gas(es) that selectively etch the dummy gates 76 and the first spacers 81 (at a faster rate than the first ILD 96, or the CESL 94); combinations thereof; or the like. The dummy gates 76 and the first spacers 81 may be etched to a depth D₁ below top surfaces of the first ILD 96 and the CESL 94 ranging from about 0 nm to about 200 nm. In some embodiments, the first spacers 81 may not be etched, such that the depth D₁ is 0 nm. The dummy gate structures (including the dummy gates 76 and the dummy gate dielectrics 71) and the first spacers 81 may have heights H₁ ranging from about 100 nm to about 0 nm. Although top surfaces of the dummy gates 76 and the first spacers 81 are illustrated in FIG. 15B as being level with one another following the etch processes, top surfaces of the dummy gates 76 may be disposed above or below top surfaces of the first spacers 81.

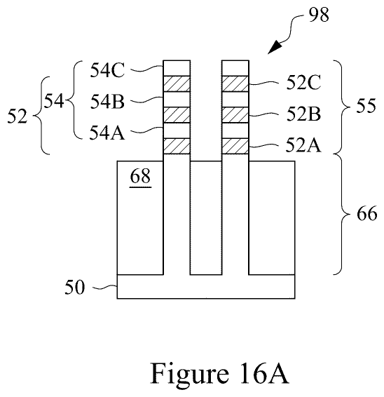

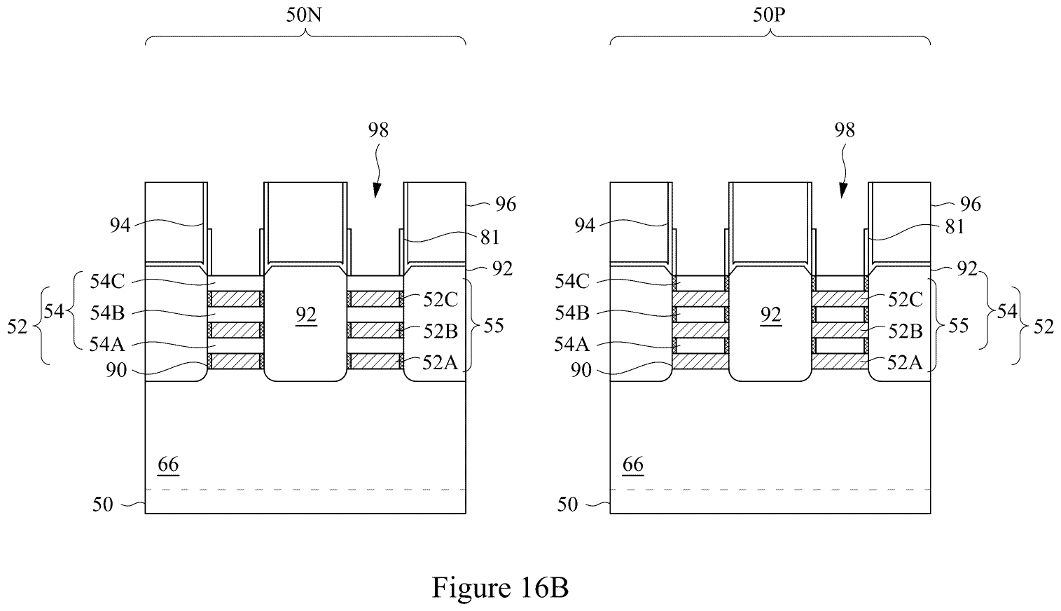

In FIGS. 16A and 16B, the dummy gates 76 and the dummy gate dielectrics 71 are removed, extending the second recesses 98. In some embodiments, the dummy gates 76 and the dummy gate dielectrics 71 are removed by one or more etch processes, such as anisotropic dry etch processes. The etch processes may include a dry etch process using reaction gas(es) that selectively etch the dummy gates 76 (at a faster rate than the first ILD 96, the CESL 94, or the first spacers 81). Each of the second recess 98 exposes and/or overlies portions of nanostructures 55, which act as channel regions in subsequently completed nanostructure FETs. The portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

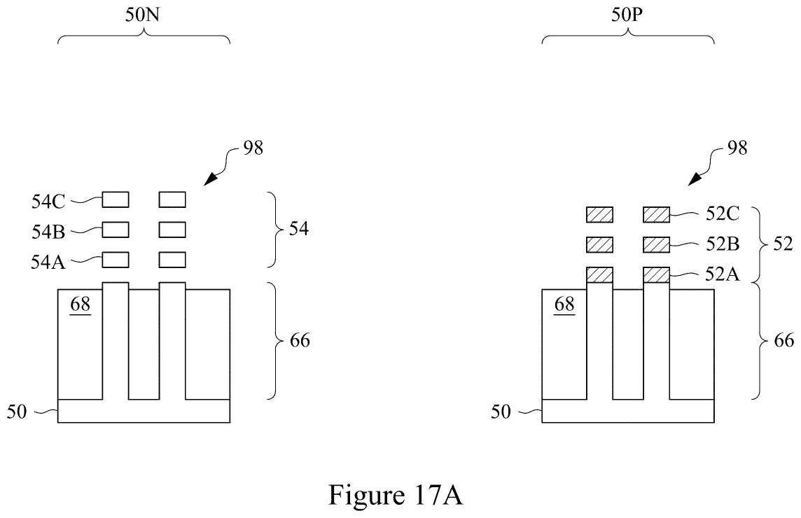

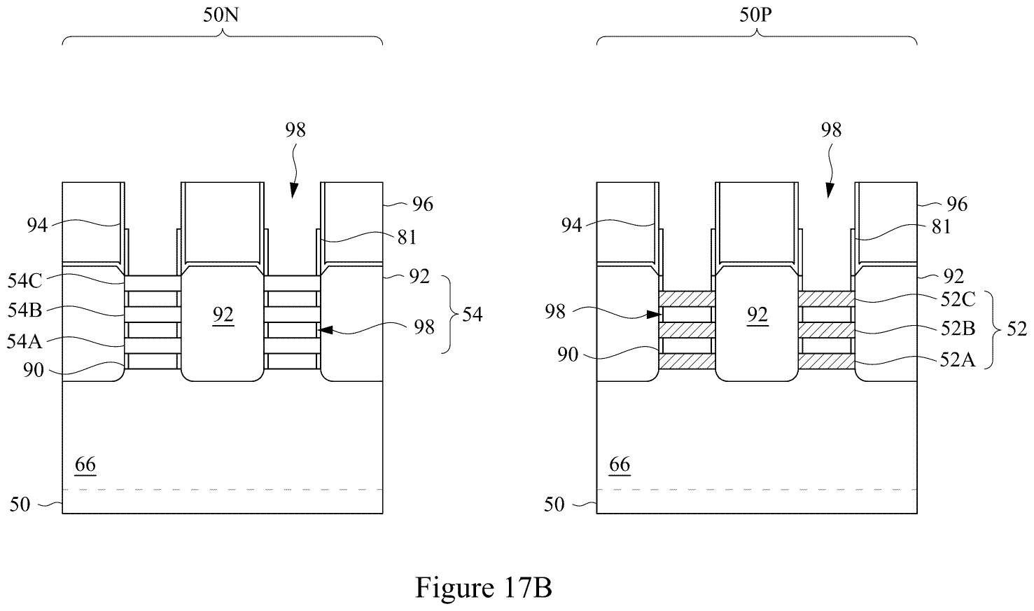

In FIGS. 17A and 17B, the first nanostructures 52 in the n-type region 50N and the second nanostructures 54 in the p-type region 50P are removed extending the second recesses 98. The first nanostructures 52 may be removed by forming a mask (not separately illustrated) over the p-type region 50P and performing an isotropic etching process, such as wet etching or the like, using etchants which are selective to the materials of the first nanostructures 52. The second nanostructures 54, the fins 66, the substrate 50, the STI regions 68, the first ILD 96, and the CESL 94 remain relatively un-etched as compared to the first nanostructures 52. In embodiments in which the first nanostructures 52 include, e.g., SiGe, and the second nanostructures 54 include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not separately illustrated) over the n-type region 50N and performing an isotropic etching process such as wet etching or the like using etchants which are selective to the materials of the second nanostructures 54. The first nanostructures 52, the fins 66, the substrate 50, the STI regions 68, the first ILD 96, and the CESL 94 remain relatively un-etched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously. For example, the first nanostructures 52 in both the n-type region 50N and the p-type region 50P may be removed, or the second nanostructures 54 in both the n-type region 50N and the p-type region 50P may be removed. In such embodiments, channel regions of n-type nanostructure FETs and p-type nanostructure FETS may have a same material composition, such as silicon, silicon carbon, silicon germanium, or the like.

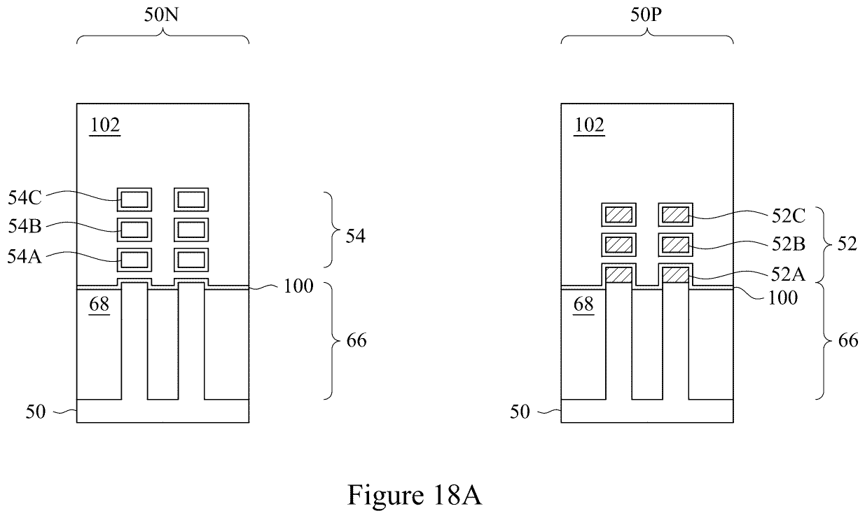

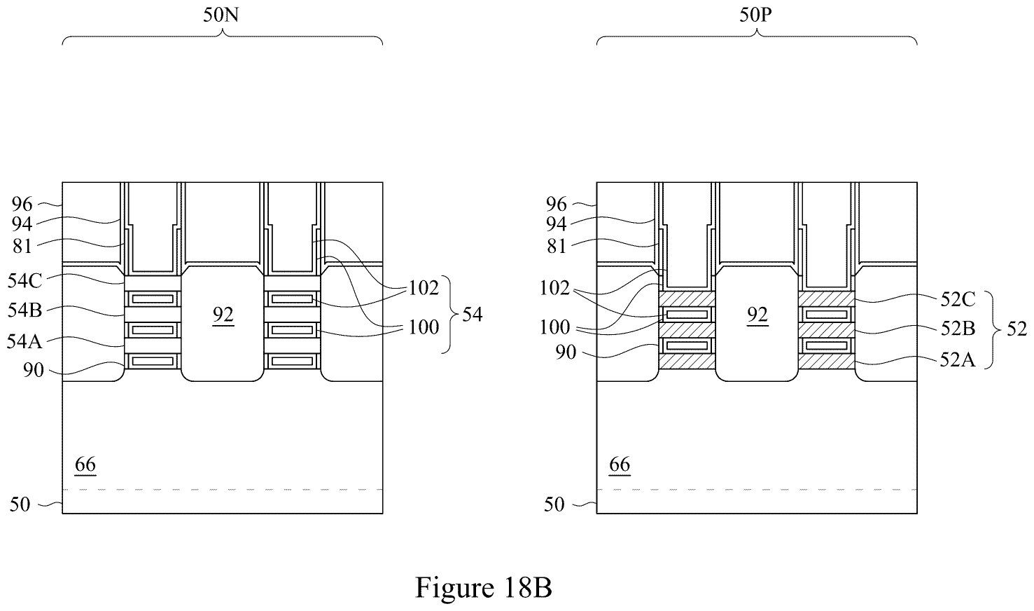

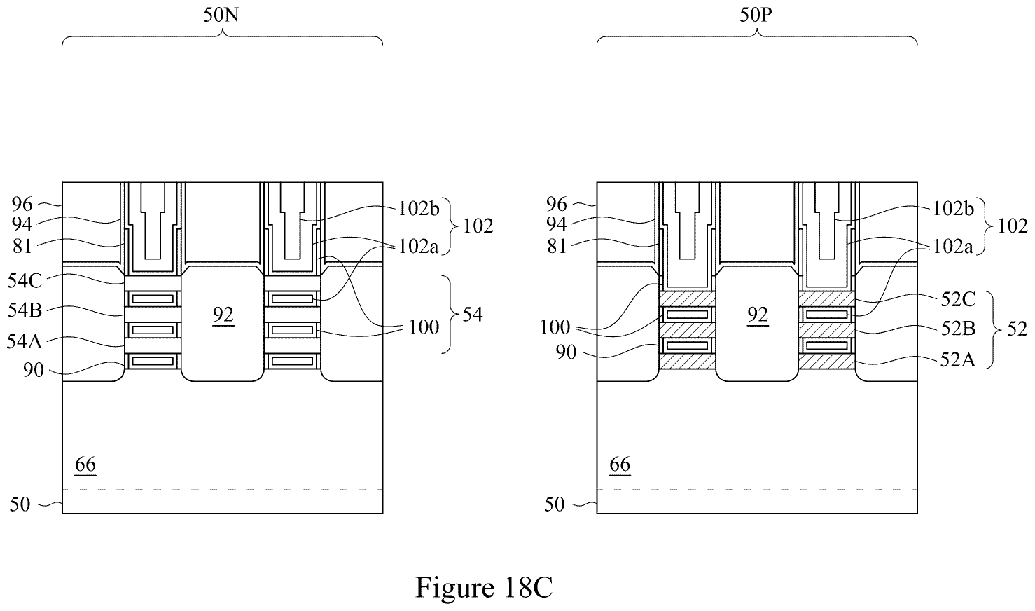

In FIGS. 18A through 18C, gate dielectric layers 100 and gate electrodes 102 are formed for replacement gates. As illustrated in FIGS. 18B and 18C, the gate dielectric layers 100 and the gate electrodes 102 may include stepped portions over the first spacers 81. The gate dielectric layers 100 are deposited conformally in the second recesses 98. In the n-type region 50N, the gate dielectric layers 100 may be formed on top surfaces and sidewalls of the fins 66 and on top surfaces, sidewalls, and bottom surfaces of the second nanostructures 54. In the p-type region 50P, the gate dielectric layers 100 may be formed on top surfaces and sidewalls of the fins 66, on top surfaces and sidewalls of the first nanostructures 52A, and on top surfaces, sidewalls, and bottom surfaces of the first nanostructures 52B and 52C. The gate dielectric layers 100 may also be deposited on top surfaces of the first ILD 96, the CESL 94, and the STI regions 68; on top surfaces and sidewalls of the first spacers 81; and on sidewalls of the first inner spacers 90.

In some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k-value greater than about 7.0. The gate dielectric layers 100 may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. Although single layer gate electrodes 102 are illustrated in FIGS. 18A and 18B, the gate electrodes 102 may comprise any number of liner layers, any number of work function tuning layers, and a fill material. As an example, FIG. 18C illustrates an embodiment in which the gate electrodes 102 comprise a first conductive material 102a and a second conductive material 102b. The first conductive material 102a and the second conductive material 102b may include any of the above-described materials for the gate electrodes 102. In some embodiments, the first conductive material 102a may include titanium nitride, aluminum, combinations thereof, or the like, and the second conductive material 102b may include tungsten or the like. Any combination of the layers which make up the gate electrodes 102 may be deposited in the n-type region 50N between adjacent ones of the second nanostructures 54 and between the second nanostructures 54A and the fins 66. Further, any combination of the layers which make up the gate electrodes 102 may be deposited in the p-type region 50P between adjacent ones of the first nanostructures 52.

The formation of the gate dielectric layers 100 in the n-type region 50N and the p-type region 50P may occur simultaneously, such that the gate dielectric layers 100 in each region are formed from the same materials. In some embodiments, the gate dielectric layers 100 in each region may be formed by distinct processes, such that the gate dielectric layers 100 may be different materials and/or have a different number of layers. The formation of the gate electrodes 102 in the n-type region 50N and the p-type region 50P may occur simultaneously such that the gate electrodes 102 in each region are formed from the same materials. The gate electrodes 102 in each region may be formed by distinct processes, such that the gate electrodes 102 may be different materials and/or have a different number of layers. Various masking steps may be used to mask and expose appropriate regions when using distinct processes. After the second recesses 98 are filled, a planarization process, such as a CMP, may be performed to remove excess portions of the gate dielectric layers 100 and the material of the gate electrodes 102, which excess portions are over top surfaces of the first ILD 96 and the CESL 94.

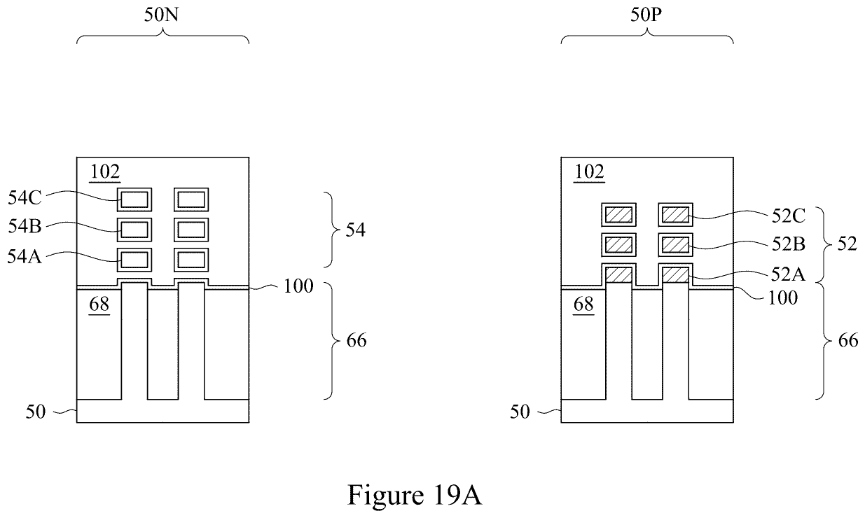

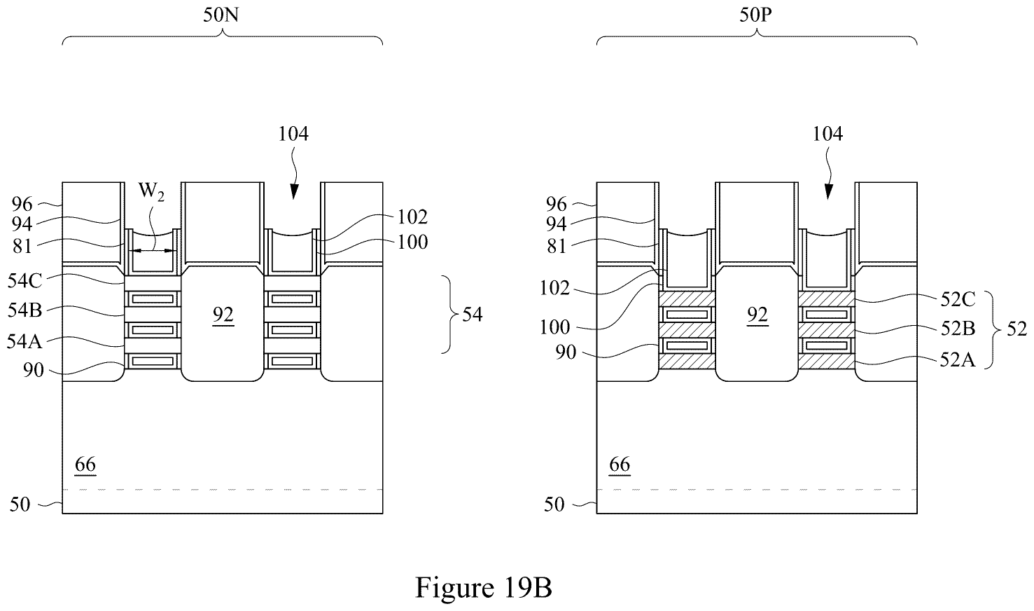

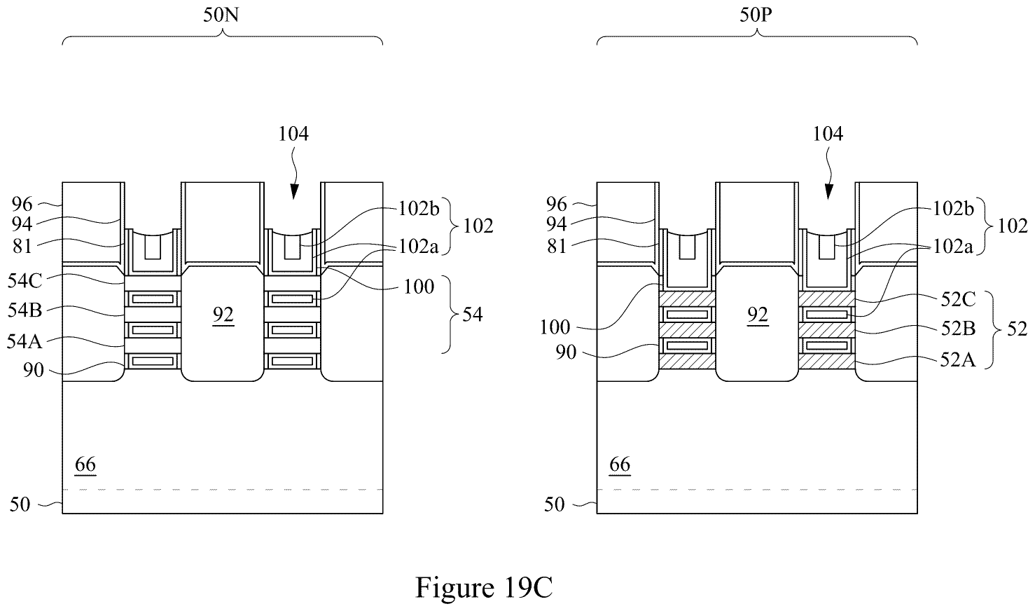

In FIGS. 19A through 19C, the gate dielectric layers 100 and the gate electrodes 102 are etched back to form third recesses 104. In some embodiments, the gate dielectric layers 100 and the gate electrodes 102 are etched back by one or more etch processes, such as anisotropic dry etch processes, isotropic wet etch processes, or the like. The etch processes may include dry etch processes using reaction gas(es) that selectively etch the gate dielectric layers 100 and the gate electrodes 102 (at a faster rate than the first ILD 96, the CESL 94, or the first spacers 81). In some embodiments, the etch processes may be performed using an etching gas comprising Cl₂, SiCl₄, CH₄, CF₄, BCl₃, Ar, O₂, combinations thereof, or the like. In some embodiments, the etch processes may be performed using a mixture of Cl₂ and BCl₃ gases. In embodiments in which the etch processes are performed using the mixture of Cl₂ and BCl₃ gases, a ratio of BCl₃ to Cl₂ may range from about 200 to about 0. As illustrated in FIGS. 19B and 19C, following the etch processes, the gate electrodes 102 may have concave surfaces, with central portions of the gate electrodes 102 being etched to a greater depth than edge portions of the gate electrodes 102. Top surfaces of the gate electrodes 102 may be disposed below top surfaces of the gate dielectric layers 100. The top surfaces of the gate dielectric layers 100 are illustrated as being level with top surfaces of the first spacers 81; however, the top surfaces of the gate dielectric layers 100 may be disposed above or below the top surfaces of the first spacers 81. The gate dielectric layers 100 and the gate electrodes 102 may have collective widths W₂ adjacent the first spacers 81 ranging from about 1 nm to about 40 nm.

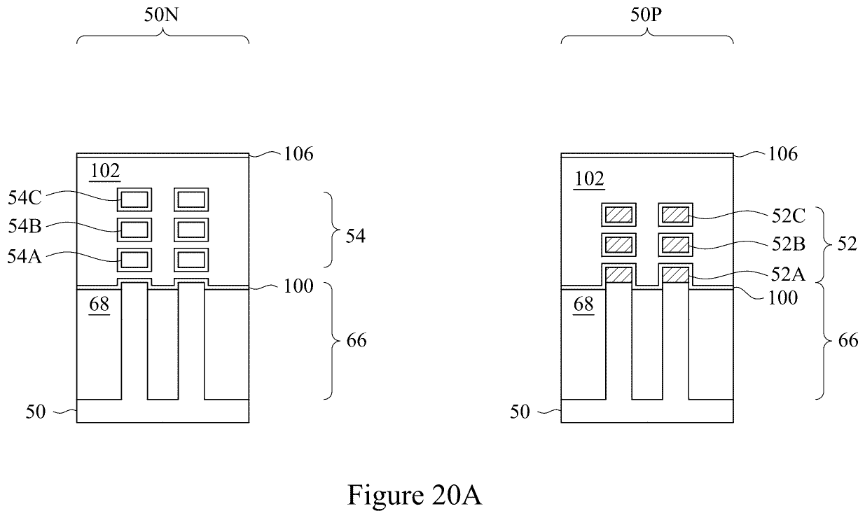

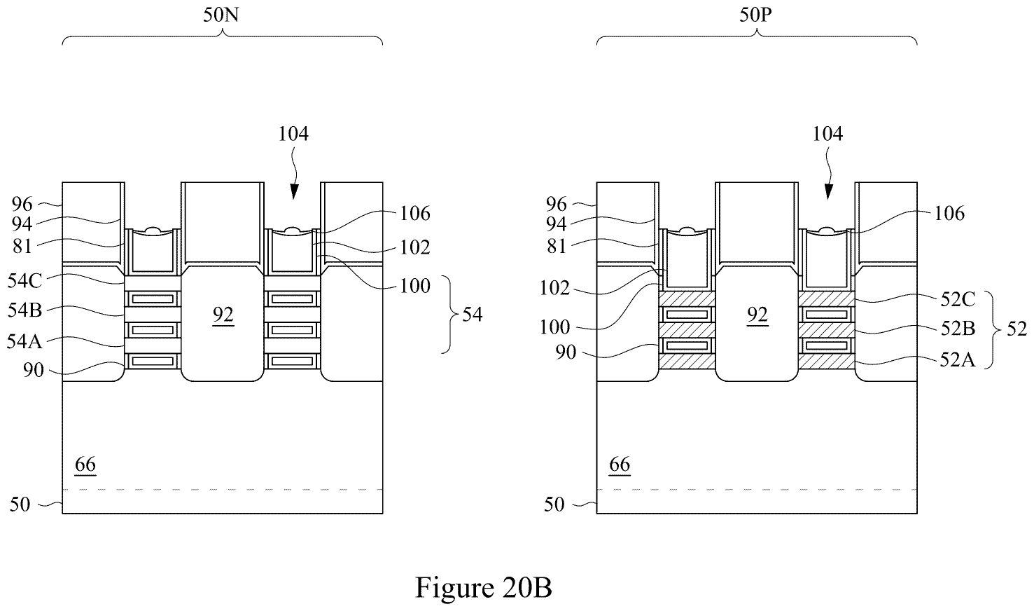

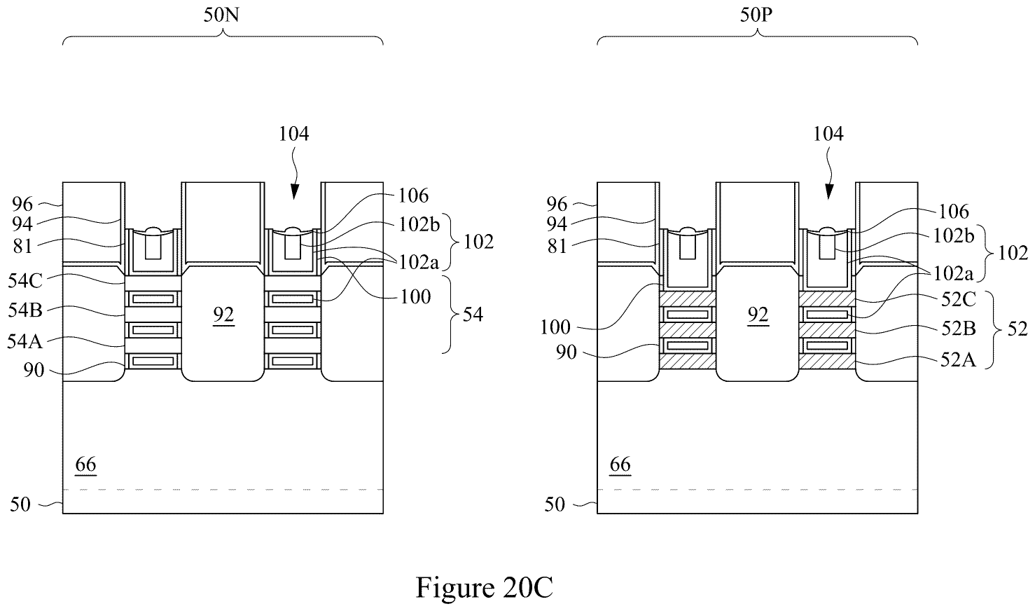

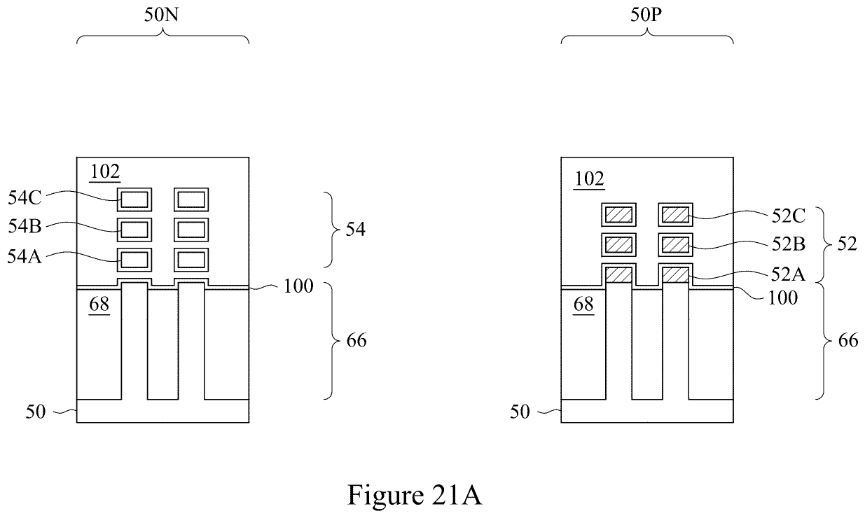

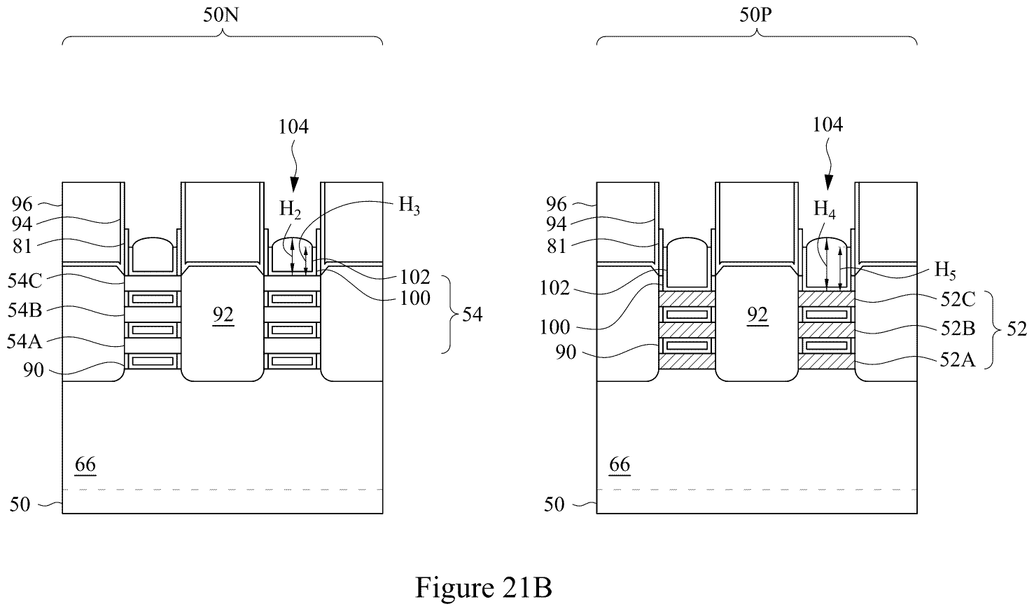

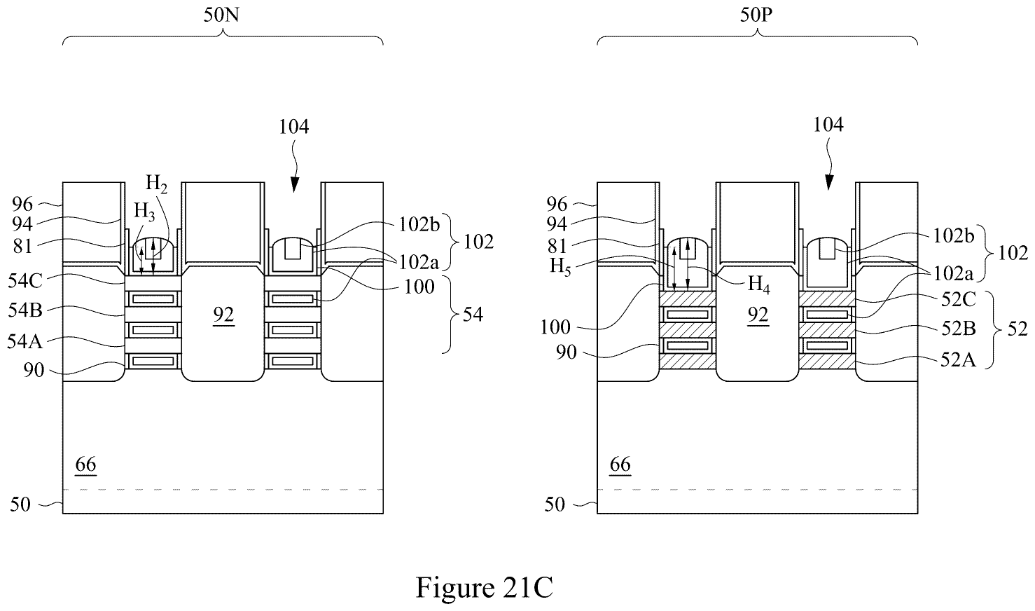

In FIGS. 20A through 20C, a gate mask 106 is selectively deposited over the gate electrodes 102. In some embodiments, the gate mask 106 may be formed of a polymer including carbon, boron, and nitrogen; a fluoropolymer (such as polytetrafluoroethylene (PTFE)); combinations thereof; or the like. In embodiments in which the gate mask 106 includes a polymer including boron and nitrogen, the gate mask 106 may be deposited by supplying a gas including a mixture of BCl₃, N₂, and/or O₂ gases. The gas may include a BCl₃ to N₂ ratio ranging from about 0.25 to about 4.0. As illustrated in FIGS. 20B and 20C, the gate mask 106 may be selectively deposited on the gate electrodes 102 (at a faster rate than the first ILD 96, the CESL 94, the first spacers 81, or the gate dielectric layers 100) and the gate mask 106 may be deposited with a greater thickness over central portions of the gate electrodes 102 than at edge portions of the gate electrodes 102. The gate mask 106 may have a greater deposition rate over the gate electrodes 102 than the gate dielectric layers 100, which results in the gate mask 106 being deposited with a greater thickness over the centers of the gate electrodes 102 than edge portions of the gate electrodes near the gate dielectric layers 100. The gate mask 106 may be deposited with a thickness ranging from about 1 nm to about 10 nm. Thicknesses of the gate mask 106 over the central portions of the gate electrodes 102 may range from about 3 nm to about 10 nm; thicknesses of the gate mask 106 over the edge portions of the gate electrodes 102 may range from about 0 nm to about 1 nm; and ratios of the thicknesses of the gate mask 106 over the central portions of the gate electrodes 102 to the thicknesses of the gate mask 106 over the edge portions of the gate electrodes 102 may range from about 3 to about 10. Depositing the gate mask 106 with a greater thickness over central portions of the gate electrodes 102 than over edge portions of the gate electrodes 102 helps to ensure that top surfaces of the gate electrodes 102 are flat or convex following a subsequent etching process (discussed with respect to FIGS. 21A through 21C). As will be discussed in greater detail subsequently, this helps to reduce device defects and improve device performance.

In FIGS. 21A through 21C, the gate masks 106 are removed and the underlying gate dielectric layers 100 and gate electrodes 102 are etched back. The gate electrodes 102 may be etched such that top surfaces of the gate electrodes 102 are flat or convex. In some embodiments, the gate masks 106, the gate dielectric layers 100, and the gate electrodes 102 are etched back by one or more etch processes, such as anisotropic dry etch processes, isotropic wet etch processes, or the like. The etch processes may include dry etch processes using reaction gas(es) that selectively etch the gate masks 106, the gate dielectric layers 100, and the gate electrodes 102 (at a faster rate than the first ILD 96, the CESL 94, or the first spacers 81). In some embodiments, the etch processes may be performed using an etching gas comprising Cl₂, SiCl₄, CH₄, CF₄, BCl₃, Ar, O₂, combinations thereof, or the like. In some embodiments, the etch processes may be performed using a mixture of Cl₂ and BCl₃ gases. In embodiments in which the etch processes are performed using the mixture of Cl₂ and BCl₃ gases, a ratio of BCl₃ to Cl₂ may range from about 10 to about 40.

Because the gate mask 106 has a greater thickness over central portions of the gate electrodes 102 than over edge portions of the gate electrodes 102, the gate mask 106 may be etched through at the edge portions faster than at the central portions, and the edge portions of the gate electrodes 102 may be etched to a greater extent than the central portions of the gate electrodes 102. Moreover, because the gate dielectric layers 100 are free from the gate mask 106, the gate dielectric layers 100 may be etched to a greater extent than the gate electrodes 102. Thus, as illustrated in FIGS. 21B and 21C, the gate electrodes 102 may have convex top surfaces, which are disposed above top surfaces of the gate dielectric layers 100. In some embodiments, the gate electrodes 102 may have flat top surfaces, which may be disposed above or level with the top surfaces of the gate dielectric layers 100. As illustrated in FIGS. 21B and 21C, the gate electrodes 102 in the n-type region 50N may have heights H₂ above top surfaces of the second nanostructures 54C ranging from about 1 nm to about 22 nm; the gate dielectric layers 100 in the n-type region 50N may have heights H₃ above top surfaces of the second nanostructures 54C ranging from about 1 nm to about 20 nm; the gate electrodes 102 in the p-type region 50P may have heights H₄ above top surfaces of the first nanostructures 52C ranging from about 1 nm to about 22 nm; and the gate dielectric layers 100 in the p-type region 50P may have heights H₅ above top surfaces of the first nanostructures 52C ranging from about 1 nm to about 20 nm. A ratio of the heights H₂ to the heights H₃ may range from about 1.1 to about 2 and a ratio of the heights H₄ to the heights H₅ may range from about 1.1 to about 2.

In FIGS. 22A through 22E, conductive caps 108 are formed over the gate dielectric layers 100 and the gate electrodes 102. The conductive caps 108 may be deposited by a process such as ALD, CVD, PVD, or the like. As illustrated in FIGS. 22B and 22C, the conductive caps 108 may be selectively deposited on the gate electrodes 102 (at a faster rate than the first ILD 96, the CESL 94, the first spacers 81, or the gate dielectric layers 100). The conductive caps 108 may be deposited by a conformal deposition process, such that top surfaces of the conductive caps 108 have profiles the same as or similar to the top surfaces of the gate electrodes 102 and the gate dielectric layers 100. In some embodiments, the conductive caps 108 may be formed by ALD, and precursors for the conductive caps 108 may include a combination of tungsten chloride (WCl₅) and hydrogen (H₂); a combination of tungsten fluoride (WF₆) and hydrogen; or the like. The process parameters for the deposition of the conductive caps 108 may be controlled to provide the selective deposition of the conductive caps 108. In the embodiments illustrated in FIGS. 22B and 22C, the gate electrodes 102 have convex top surfaces and the conductive caps 108 have flat top surfaces. In the embodiments illustrated in FIGS. 22D and 22E, the gate electrodes 102 have convex top surfaces and the conductive caps 108 have convex top surfaces. The conductive caps 108 may include a material such as tungsten, cobalt, or the like. The conductive caps 108 may have widths W₃ adjacent the first spacers 81 ranging from about 1 nm to about 40 nm. The conductive caps 108 may have thicknesses ranging from about 0 nm to about 10 nm.

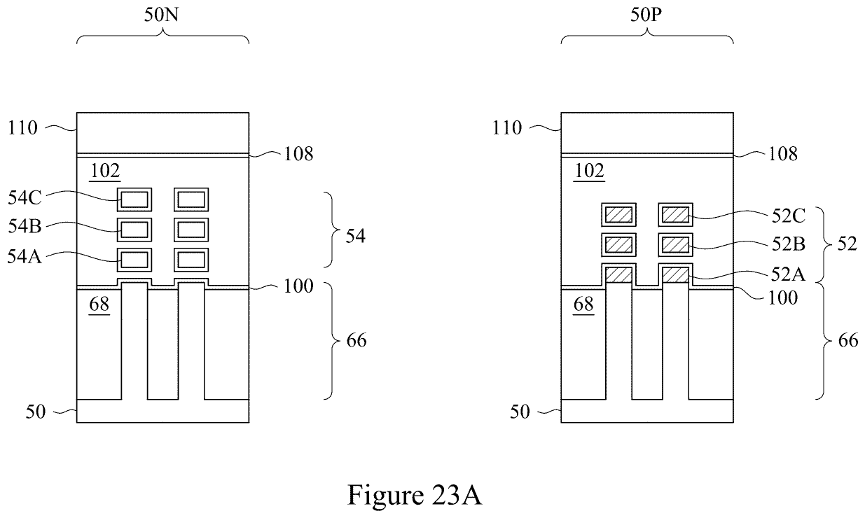

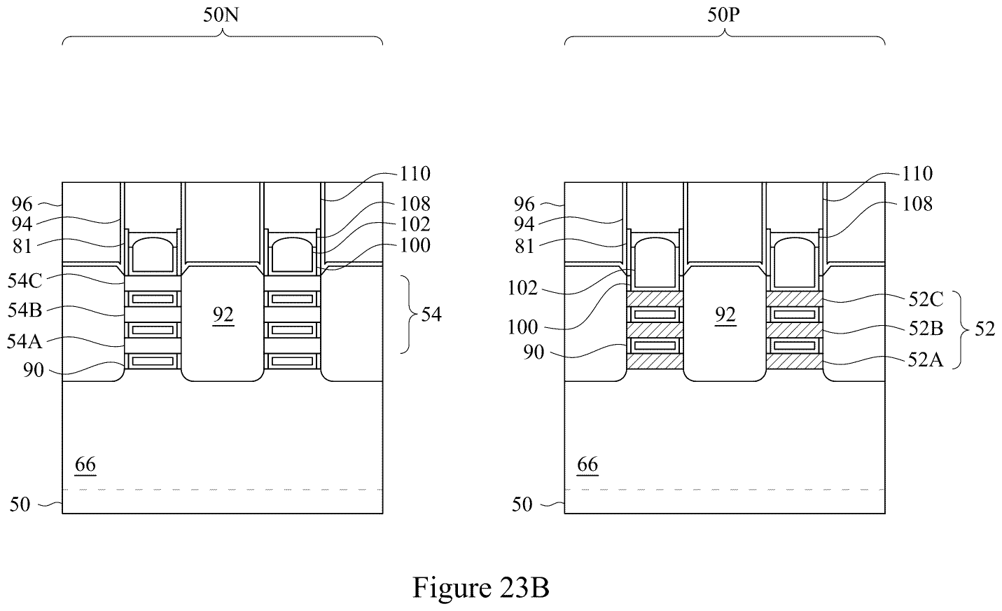

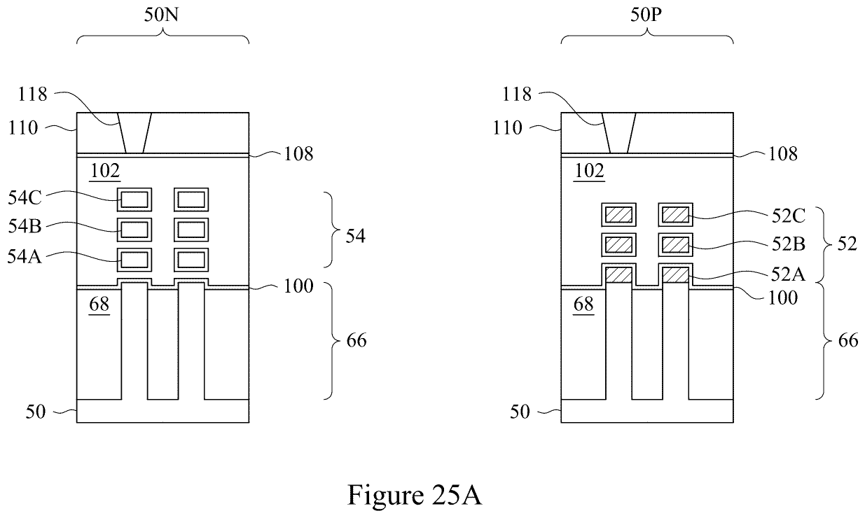

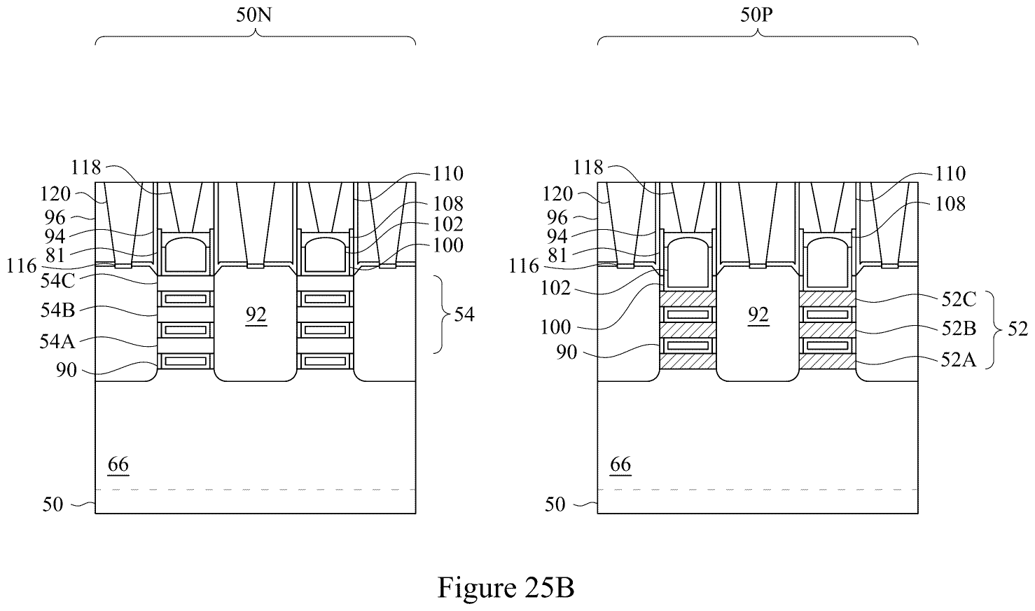

Forming the conductive caps 108 with flat top surfaces or convex top surfaces helps to prevent under-etching of a dielectric layer (such as the second ILD 110, discussed below with respect to FIGS. 23A and 23B) during the subsequent formation of gate contacts (such as the gate contacts 118, discussed below with respect to FIGS. 25A and 25B) through the dielectric layer to the conductive caps 108. This prevents device defects and improves device performance. Moreover, forming the conductive caps 108 with flat top surfaces or convex top surfaces increases a distance between the conductive caps 108 and subsequently formed source/drain contacts (such as the source/drain contacts 120, discussed below with respect to FIGS. 25A and 25B), which prevents bridging, and further helps to prevent device defects and improve device performance.

The gate dielectric layers 100, the gate electrodes 102, and the conductive caps 108 form replacement gate structures of the resulting nanostructure FETs. The gate dielectric layers 100, the gate electrodes 102, and the conductive caps 108 may be collectively referred to as “gate structures.” The epitaxial source/drain regions 92, the first nanostructures 52/second nanostructures 54, and the gate structures (including the gate dielectric layers 100, the gate electrodes 102, and the conductive caps 108) may collectively be referred to as transistor structures 109.

In FIGS. 23A and 23B, a second ILD 110 is deposited over the conductive caps 108, the first spacers 81, the CESL 94, and the first ILD 96 filling the third recesses 104. In some embodiments, the second ILD 110 is a flowable film formed by FCVD. In some embodiments, the second ILD 110 is formed of a dielectric material such as PSG, BSG, BPSG, USG, or the like, and may be deposited by any suitable method, such as CVD, PECVD, or the like. After the second ILD 110 is deposited, the second ILD 110 is planarized. The second ILD 110 may be planarized by a process such as CMP. Portions of the second ILD 110 disposed above the first ILD 96 and the CESL 94 may be removed and, following the planarization, top surfaces of the first ILD 96 and the CESL 94 may be level with top surfaces of the second ILD 110.

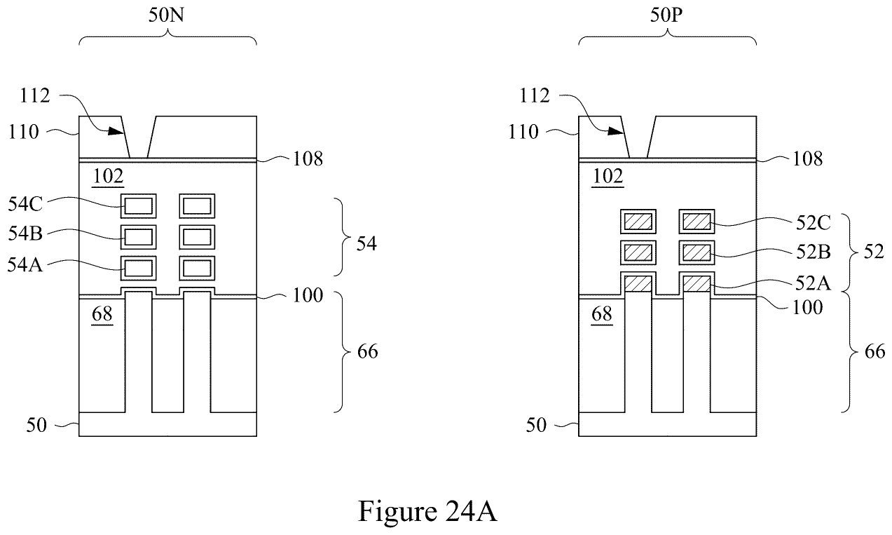

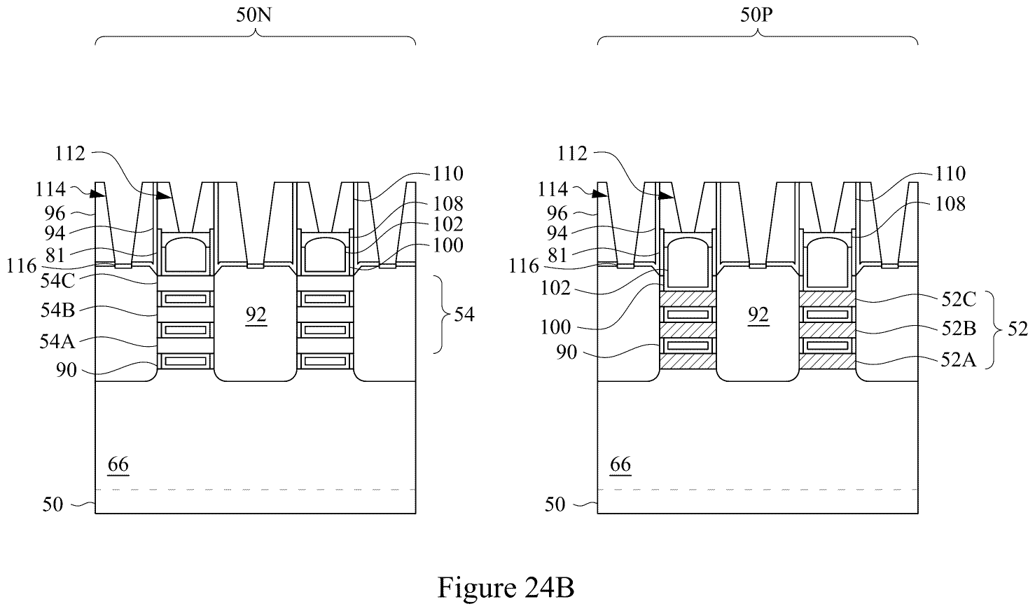

In FIGS. 24A and 24B, the second ILD 110 is etched to form fourth recesses 112 exposing surfaces of the conductive caps 108 and the first ILD 96 and the CESL 94 are etched to form fifth recesses 114 exposing surfaces of the epitaxial source/drain regions 92. The fourth recesses 112 and the fifth recesses 114 may be formed by etching using an anisotropic etch process, such as RIE, NBE, or the like. The fourth recesses 112 and the fifth recesses 114 may be formed simultaneously or separately. In some embodiments, the fourth recesses 112 and the fifth recesses 114 may be etched through the second ILD 110 and the first ILD 96 using a first etch process and the fifth recesses 114 may then be etched through the CESL 94 using a second etch process. A mask, such as a photoresist, may be formed and patterned over the first ILD 96, the CESL 94, and the second ILD 110 to mask portions of the first ILD 96, the CESL 94, and the second ILD 110 from the first etch process and the second etch process. In some embodiments, the etch processes may over-etch, and therefore, the fourth recesses 112 and the fifth recesses 114 extend into the conductive caps 108 and/or the epitaxial source/drain regions 92. Although FIG. 24B illustrates the fourth recesses 112 and the fifth recesses 114 as exposing the conductive caps 108 and the epitaxial source/drain regions 92 in a same cross-section, in some embodiments, the conductive caps 108 and the epitaxial source/drain regions 92 may be exposed in different cross-sections, thereby reducing the risk of shorting subsequently formed contacts.

Forming the conductive caps 108 with the flat top surfaces or convex top surfaces, as described above, may reduce under-etching of the second ILD 110 during the formation of the fourth recesses 112. For example, if the conductive caps 108 are formed with concave top surfaces, portions of the second ILD 110 disposed in low point of the concave top surfaces of the conductive caps 108 may remain after forming the fourth recesses 112. This may increase resistance between the conductive caps 108 and subsequently formed gate contacts, cause device defects, and reduce device performance. Further, by etching the gate electrodes 102 and the gate dielectric layers 100 through the gate mask 106 and forming the conductive caps 108 with flat top surfaces or convex top surfaces, distances between the conductive caps 108 and the fifth recesses 114 are increased, which reduces the likelihood of bridging occurring between gate contacts formed in the fourth recesses 112 and source/drain contacts formed in the fifth recesses 114. This further reduces device defects and improves device performance.

After the fifth recesses 114 are formed, silicide regions 116 may be formed over the epitaxial source/drain regions 92. In some embodiments, the silicide regions 116 are formed by first depositing a metal (not separately illustrated) capable of reacting with the semiconductor materials of the underlying epitaxial source/drain regions 92 (e.g., silicon, silicon germanium, germanium, or the like) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 116. The un-reacted portions of the deposited metal are then removed, e.g., by an etching process. Although silicide regions 116 are referred to as silicide regions, silicide regions 116 may also be germanide regions, or silicon germanide regions (e.g., regions comprising silicide and germanide).

In FIGS. 25A and 25B, gate contacts 118 are formed in the fourth recesses 112 and source/drain contacts 120 are formed in the fifth recesses 114. The gate contacts 118 and the source/drain contacts 120 may each comprise one or more layers, such as barrier layers, diffusion layers, and fill materials. For example, in some embodiments, the gate contacts 118 and the source/drain contacts 120 each include a barrier layer and a conductive material over the barrier layer. The gate contacts 118 and the source/drain contacts 120 are each electrically coupled to underlying conductive features (e.g., the conductive caps 108 and/or the silicide regions 116). The gate contacts 118 are electrically coupled to the conductive caps 108 of the gate structures, and the source/drain contacts 120 are electrically coupled to the silicide regions 116 over the epitaxial source/drain regions 92. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from surfaces of the CESL 94, the first ILD 96, and the second ILD 110 such that top surfaces of the gate contacts 118 and the source/drain contacts 120 are level with top surfaces of the CESL 94, the first ILD 96, and the second ILD 110.

Embodiments may achieve advantages. For example, forming the conductive caps 108 with the flat top surfaces or convex top surfaces, as described above, may reduce under-etching of the second ILD 110, decreasing resistance between the gate contacts 118 and the conductive caps 108, reducing device defects, and improving device performance. Further, by forming the conductive caps 108 with flat top surfaces or convex top surfaces, distances between the source/drain contacts 120 and the conductive caps 108 may be increased, reducing the likelihood of bridging between the source/drain contacts 120 and the conductive caps 108, reducing device defects, and further improving device performance.

In accordance with an embodiment, a semiconductor device includes a gate structure over a semiconductor substrate, the gate structure including a high-k dielectric layer; a gate electrode over the high-k dielectric layer; a conductive cap over and in contact with the high-k dielectric layer and the gate electrode, a top surface of the conductive cap being convex; and first gate spacers on opposite sides of the gate structure, the high-k dielectric layer and the conductive cap extending between opposite sidewalls of the first gate spacers. In an embodiment, a top surface of the gate electrode is convex. In an embodiment, a top surface of the gate electrode is disposed above a top surface of the high-k dielectric layer. In an embodiment, the semiconductor device further includes a first interlayer dielectric (ILD) layer over the gate structure and the first gate spacers; and a gate contact extending through the first ILD layer, the gate contact being in physical contact with the top surface of the conductive cap, and the gate contact being electrically coupled to the gate structure. In an embodiment, the semiconductor device further includes an etch stop layer on opposite sides of the first gate spacers, the first ILD layer extends between opposite sidewalls of the etch stop layer, and a top surface of the first ILD layer, a top surface of the etch stop layer, and a top surface of the gate contact are level with one another. In an embodiment, bottom surfaces of the first gate spacers are level with a bottom surface of the etch stop layer. In an embodiment, the top surface of the conductive cap is disposed below top surfaces of the first gate spacers.

In accordance with another embodiment, a semiconductor device includes a first channel region over a semiconductor substrate; and a first gate stack over the first channel region, the first gate stack including a first gate dielectric layer over the first channel region; a first gate electrode over the first gate dielectric layer, the first gate electrode includes a first convex top surface; and a first conductive cap over the first gate electrode, the first conductive cap including a flat top surface or a second convex top surface. In an embodiment, the first gate dielectric layer has a first height above the first channel region, the first gate electrode has a second height above the first channel region, and the second height is greater than the first height. In an embodiment, a ratio of the second height to the first height is from 1.2 to 2.0. In an embodiment, the semiconductor device further includes first gate spacers adjacent opposite sidewalls of the first gate stack, the first gate dielectric layer and the first conductive cap contacting the first gate spacers. In an embodiment, a first distance between a top surface of the first gate spacers and a top surface of the semiconductor substrate is greater than a second distance between a top surface of the first conductive cap and the top surface of the semiconductor substrate. In an embodiment, the first conductive cap contacts the first convex top surface of the first gate electrode and a top surface of the first gate dielectric layer.

In accordance with yet another embodiment, a method includes removing a dummy gate structure from between opposite sidewalls of a first gate spacer to form a first opening; depositing a dielectric layer in the first opening; depositing a gate electrode in the first opening over the dielectric layer; etching back the dielectric layer and the gate electrode with a first etch process; depositing a first polymer material over the gate electrode; etching back the first polymer material, the gate electrode, and the dielectric layer with a second etch process; and depositing a conductive cap over and in contact with the gate electrode and the dielectric layer. In an embodiment, the gate electrode has a concave top surface after the first etch process, and the gate electrode has a convex top surface after the second etch process. In an embodiment, the conductive cap is deposited with a top surface which is flat or convex. In an embodiment, depositing the first polymer material over the gate electrode includes a deposition process which uses BCl₃ and N₂ as reactants. In an embodiment, a ratio of a flowrate of BCl₃ to a flowrate of N₂ used during the depositing the first polymer material over the gate electrode ranges from 0.25 to 4.0. In an embodiment, the first etch process and the second etch process use reactants including Cl₂ and BCl₃. In an embodiment, a ratio of a flowrate of BCl₃ to a flowrate of Cl₂ used during the second etch process ranges from 10 to 40.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a gate structure over a semiconductor substrate, the gate structure comprising:
a high-k dielectric layer;
a gate electrode over the high-k dielectric layer;
a conductive cap over and in contact with the high-k dielectric layer and the gate electrode, wherein a top surface of the conductive cap is convex; and
first gate spacers on opposite sides of the gate structure, wherein the high-k dielectric layer and the conductive cap extend between opposite sidewalls of the first gate spacers.

2. The semiconductor device of claim 1, wherein a top surface of the gate electrode is convex.

3. The semiconductor device of claim 1, wherein a top surface of the gate electrode is disposed above a top surface of the high-k dielectric layer.

4. The semiconductor device of claim 1, further comprising:
a first interlayer dielectric (ILD) layer over the gate structure and the first gate spacers; and
a gate contact extending through the first ILD layer, wherein the gate contact is in physical contact with the top surface of the conductive cap, and wherein the gate contact is electrically coupled to the gate structure.

5. The semiconductor device of claim 4, further comprising an etch stop layer on opposite sides of the first gate spacers, wherein the first ILD layer extends between opposite sidewalls of the etch stop layer, and wherein a top surface of the first ILD layer, a top surface of the etch stop layer, and a top surface of the gate contact are level with one another.

6. The semiconductor device of claim 5, wherein bottom surfaces of the first gate spacers are level with a bottom surface of the etch stop layer.

7. The semiconductor device of claim 1, wherein the top surface of the conductive cap is disposed below top surfaces of the first gate spacers.

8. A semiconductor device comprising:
a first channel region over a semiconductor substrate; and
a first gate stack over the first channel region, the first gate stack comprising:
a first gate dielectric layer over the first channel region;
a first gate electrode over the first gate dielectric layer, the first gate electrode comprising a first convex top surface; and
a first conductive cap over the first gate electrode, the first conductive cap comprising a flat top surface or a second convex top surface.

9. The semiconductor device of claim 8, wherein the first gate dielectric layer has a first height above the first channel region, wherein the first gate electrode has a second height above the first channel region, and wherein the second height is greater than the first height.

10. The semiconductor device of claim 9, wherein a ratio of the second height to the first height is from 1.1 to 2.0.

11. The semiconductor device of claim 8, further comprising first gate spacers adjacent opposite sidewalls of the first gate stack, wherein the first gate dielectric layer and the first conductive cap contact the first gate spacers.

12. The semiconductor device of claim 11, wherein a first distance between a top surface of the first gate spacers and a top surface of the semiconductor substrate is greater than a second distance between a top surface of the first conductive cap and the top surface of the semiconductor substrate.

13. The semiconductor device of claim 8, wherein the first conductive cap contacts the first convex top surface of the first gate electrode and a top surface of the first gate dielectric layer.

14. A semiconductor device comprising:
a gate structure over a channel region of a semiconductor substrate, the gate structure comprising:
a high-k dielectric layer;
a gate electrode over the high-k dielectric layer;
a conductive cap over and in contact with the high-k dielectric layer and the gate electrode, wherein the conductive cap extends between the gate electrode and the high-k dielectric layer along a line parallel to a major surface of the semiconductor substrate; and
first gate spacers on opposite sides of the gate structure, wherein the high-k dielectric layer and the conductive cap extend between opposite sidewalls of the first gate spacers.

15. The semiconductor device of claim 14, wherein the conductive cap has a flat upper surface.

16. The semiconductor device of claim 14, wherein the conductive cap has a convex upper surface.

17. The semiconductor device of claim 14, wherein an upper surface of the conductive cap is below an upper surface of the high-k dielectric layer.

18. The semiconductor device of claim 14, wherein an upper surface of the high-k dielectric layer is a first distance above the channel region, wherein an upper surface of the gate electrode is a second distance above the channel region, and wherein the second distance is greater than the first distance.

19. The semiconductor device of claim 18, wherein a ratio of the second distance to the first distance is from 1.2 to 2.0.

20. The semiconductor device of claim 14, further comprising:
a dielectric layer over the conductive cap, wherein the dielectric layer contacts the high-k dielectric layer, wherein the dielectric layer is between the first gate spacers.
